(19) United States
(12) Patent Application Publication
(10) Pub. No.: US 2026/0255777 A1
(43) Pub. Date: Aug. 27, 2026

(54) METHOD OF FORMING LIGHT-EMITTING LAYER, METHOD OF MANUFACTURING DISPLAY DEVICE, AND DISPLAY DEVICE

(71) Applicant: SHARP DISPLAY TECHNOLOGY CORPORATION, Kameyama City, Mie (JP)

(72) Inventors: Hirohisa YAMADA, Kameyama City, Mie (JP); Yuma YAGUCHI, Kameyama City, Mie (JP); Kazuki MARUHASHI, Kameyama City, Mie (JP)

(21) Appl. No.: 18/726,990

(22) PCT Filed: Mar. 8, 2022
(86) PCT No.: PCT/JP2022/009846

§ 371 Date: Jul. 5, 2024

(51) Int. Cl. H10K 50/115; H10K 59/12

(52) U.S. Cl. CPC H10K 50/115; H10K 59/1201

(57) ABSTRACT

A method of forming a red light-emitting layer includes: a light-emitting layer formation step of forming a red light-emitting layer containing either quantum dots each including a core or quantum dots each including a core and a shell; and a light-emitting layer processing step of treating the quantum dots in the red light-emitting layer with a treating agent after the light-emitting layer formation step of forming the red light-emitting layer.

### TECHNICAL FIELD

The present disclosure relates to methods of forming a light-emitting layer, methods of manufacturing a display device, and display devices.

### BACKGROUND ART

Various display devices have been developed incorporating light-emitting elements. Display devices incorporating QLEDs (quantum-dot light-emitting diodes) are especially of high interest for, among other reasons, their low power consumption, small thickness, and high image quality.

Patent Literature 1 describes treating, with a reducing agent, the surface of semiconductor nanocrystals (quantum dots) that are used in a step of forming a light-emitting layer in the QLEDs in the liquid phase.

### CITATION LIST

### Patent Literature

Patent Literature 1: Japanese Unexamined Patent Application Publication No. 2005-101601

### SUMMARY

### Technical Problem

As described in Patent Literature 1, the semiconductor nanocrystals (quantum dots) the surface of which has been treated with a reducing agent in the liquid phase are manufactured before the step of forming a light-emitting layer in the QLEDs and then used in the step of forming the light-emitting layer in the QLEDs. Degradation of the semiconductor nanocrystals the surface of which has been treated with a reducing agent in the liquid phase is inevitable in the step of forming the light-emitting layer in the QLEDs. In the step of forming the light-emitting layer in the QLEDs, the semiconductor nanocrystals would degrade under the adverse effects of, for example, water and oxygen in the atmosphere and, when a resist film is used, in the steps of forming and lifting off the resist film. Such degraded semiconductor nanocrystals are undesirable because of their poor properties and could disadvantageously lead to, for example, a short fluorescence lifetime and a low luminous efficiency in display devices including the degraded semiconductor nanocrystals in the light-emitting layer.

The present disclosure, in an aspect thereof, has been made in view of these problems and has an object to provide a method of forming a light-emitting layer for improving the properties of degraded quantum dots and to provide a method of manufacturing a display device and a display device for improving, for example, fluorescence lifetime and luminous efficiency and also for allowing for streamlined manufacturing equipment and reduced manufacturing cost.

### Solution to Problem

The present disclosure, to address these problems, is directed to a method of forming a light-emitting layer, the method including:
a light-emitting layer formation step of forming a light-emitting layer containing either quantum dots each including a core or quantum dots each including a core and a shell; and
a light-emitting layer processing step of treating the quantum dots in the light-emitting layer with a reducing agent after the light-emitting layer formation step.

The present disclosure, to address the problems, is directed to a method of manufacturing a display device, the method including a step of forming a light-emitting layer on a substrate by the method of forming a light-emitting layer.

The present disclosure, to address the problems, is directed to a display device including:
a first subpixel, a second subpixel, and a third subpixel;
a first light-emitting layer provided in the first subpixel and containing either first quantum dots each including a core or first quantum dots each including a core and a shell;
a second light-emitting layer provided in the second subpixel and containing either second quantum dots each including a core or second quantum dots each including a core and a shell; and
a third light-emitting layer provided in the third subpixel and containing either third quantum dots each including a core or third quantum dots each including a core and a shell, wherein
the first light-emitting layer contains an element that has a lower electronegativity than all elements contained in the first quantum dots,
the second light-emitting layer contains an element that has a lower electronegativity than all elements contained in the second quantum dots, and
the third light-emitting layer contains an element that has a lower electronegativity than all elements contained in the third quantum dots.

### Advantageous Effects of Disclosure

The present disclosure, in an aspect thereof, can provide a method of forming a light-emitting layer for improving the properties of degraded quantum dots and to provide a method of manufacturing a display device and a display device for improving, for example, fluorescence lifetime and luminous efficiency and also for allowing for streamlined manufacturing equipment and reduced manufacturing cost.

### BRIEF DESCRIPTION OF DRAWINGS

Portions (a), (b), (c), (d), and (e) of FIG. 1 are diagrams illustrating steps of forming a light-emitting element in accordance with Embodiment 1, including a film formation step of forming a light-emitting layer containing quantum dots that have been treated with a reducing agent.

Portion (a) of FIG. 2 is a diagram illustrating a light-emitting layer containing quantum dots that are yet to be treated with a reducing agent, and portion (b) of FIG. 2 is a diagram illustrating a light-emitting layer containing quantum dots that have been treated with a reducing agent.

FIG. 3 is a diagram representing: the fluorescence lifetime of a light-emitting layer (sample A) formed by coating and medium removal in a nitrogen environment; the fluorescence lifetime of a light-emitting layer (sample B) obtained by additionally exposing the light-emitting layer (sample A) in an ambient environment for 1 hour; and the fluorescence lifetime of a light-emitting layer (sample C) obtained by additionally performing a light-emitting layer processing step shown in (b) of FIG. 1 on the light-emitting layer (sample B).

FIG. 4 is a diagram representing the internal quantum yield of the quantum dots contained in the light-emitting layer (sample A) shown in FIG. 3, the internal quantum yield of the quantum dots contained in the light-emitting layer (sample B) shown in FIG. 3, and the internal quantum yield of the quantum dots contained in the light-emitting layer (sample C) shown in FIG. 3.

Portions (a), (b), (c), (d), (e), and (f) of FIG. 5 are diagrams illustrating a patterning step for a light-emitting layer by lift-off that is a part of steps of forming a light-emitting element in accordance with Embodiment 2.

Portions (a), (b), (c), (d), and (e) of FIG. 6 are diagrams illustrating steps of forming a light-emitting element in accordance with Embodiment 2, including film formation steps of forming a light-emitting layer including a step of treating, with a reducing agent, the quantum dots contained in the light-emitting layer patterned by lift-off shown in FIG. 5.

FIG. 7 is a diagram representing: the fluorescence lifetime of a light-emitting layer (sample D) formed by coating and medium removal in a nitrogen environment; the fluorescence lifetime of a light-emitting layer (sample E) subjected to a lift-off patterning step shown in FIG. 5; and the fluorescence lifetime of a light-emitting layer (sample F) obtained by additionally performing a light-emitting layer processing step shown in (b) of FIG. 6 on the light-emitting layer (sample E).

FIG. 8 is a schematic plan view of a structure of a display device in accordance with Embodiment 3.

FIG. 9 is a schematic cross-sectional view of a structure of a substrate including transistors in the display device in accordance with Embodiment 3.

FIG. 10 is a schematic cross-sectional view of a structure of a red light-emitting element, a green light-emitting element, and a blue light-emitting element in the display device in accordance with Embodiment 3.

Portions (a) to (o) of FIG. 11 are diagrams illustrating a lift-off patterning step for a red light-emitting layer, a green light-emitting layer, and a blue light-emitting layer respectively in the red light-emitting element, the green light-emitting element, and the blue light-emitting element in the display device in accordance with Embodiment 3.

Portions (a), (b), (c), and (d) of FIG. 12 are diagrams illustrating a step of treating, with a reducing agent, the quantum dots contained in the red light-emitting layer, the green light-emitting layer, and the blue light-emitting layer patterned by lift-off shown in FIG. 11 that is a part of film formation steps of forming a light-emitting layer included in the steps of forming the display device in accordance with Embodiment 3.

Portions (a), (b), and (c) of FIG. 13 are diagrams illustrating a step of further modifying, with ligands, the quantum dots, contained in the red light-emitting layer, the green light-emitting layer, and the blue light-emitting layer, that have been treated with a reducing agent, which is performed after the step shown in FIG. 12, that is another part of the film formation steps of forming a light-emitting layer included in the steps of forming the display device in accordance with Embodiment 3.

FIG. 14 is a diagram representing the light-emission intensity of a red light-emitting element (sample G), the light-emission intensity of a red light-emitting element (sample H), the light-emission intensity of a red light-emitting element (sample I), the light-emission intensity of a red light-emitting element (sample J), and the light-emission intensity of a red light-emitting element (sample K), when the red light-emitting elements are caused to fluoresce (photoluminescence or PL) under the same excitation light.

FIG. 15 is a diagram representing results of measurement of the fluorescence lifetime of the red light-emitting element (sample H), the red light-emitting element (sample I), the red light-emitting element (sample J), and the red light-emitting element (sample K) shown in FIG. 14.

FIG. 16 is a diagram representing a relationship between a current density and luminance for the red light-emitting element (sample H), the red light-emitting element (sample I), the red light-emitting element (sample J), and the red light-emitting element (sample K) shown in FIG. 14.

FIG. 17 is a diagram representing a relationship between a current density and an external quantum efficiency (EQE) for the red light-emitting element (sample H), the red light-emitting element (sample I), the red light-emitting element (sample J), and the red light-emitting element (sample K) shown in FIG. 14.

### DESCRIPTION OF EMBODIMENTS

The following will describe embodiments of the disclosure with reference to FIGS. 1 to 17. Throughout the following, members of an embodiment that have the same arrangement and function as members of a specific embodiment are indicated by the same reference numerals and description thereof may be omitted for convenience of description.

### Embodiment 1

Portions (a) of FIG. 1, (b) of FIG. 1, (c) of FIG. 1, (d) of FIG. 1, and (e) of FIG. 1 are diagrams illustrating steps of forming a red light-emitting element 30R in accordance with Embodiment 1, including a film formation step of forming a red light-emitting layer 25R containing quantum dots that have been treated with a reducing agent.

Portion (a) of FIG. 2 is a diagram illustrating a red light-emitting layer 24R containing quantum dots QD that are yet to be treated with a reducing agent. Portion (b) of FIG. 2 is a diagram illustrating the red light-emitting layer 25R containing quantum dots QD that have been treated with a reducing agent.

As shown in (e) of FIG. 1, the present embodiment will discuss, as an example, the red light-emitting element 30R that has a forward-order stack structure including a stack of a first electrode 22, which is an anode, a hole transport layer 23, the red light-emitting layer 25R containing quantum dots treated with a reducing agent, an electron transport layer 27, and a second electrode 28, which is a cathode, all of which are provided on a substrate 42 in this order when viewed from the substrate 42, which is merely illustrative. Alternatively, the present embodiment may be applied to, for example: a green light-emitting element that has a forward-order stack structure including a green light-emitting layer containing quantum dots treated with a reducing agent; a blue light-emitting element that has a forward-order stack structure including a blue light-emitting layer containing quantum dots treated with a reducing agent; or a light-emitting element that has a forward-order stack structure including a light-emitting layer for another color containing quantum dots treated with a reducing agent. As further alternative examples (not show), the present embodiment may be applied to: a red light-emitting element that has a reverse-order stack structure including a stack of the first electrode 22, which is a cathode, the electron transport layer 27, the red light-emitting layer 25R containing quantum dots treated with a reducing agent, the hole transport layer 23, which is an anode, and the second electrode 28, all of which are provided on the substrate 42 in this order when viewed from the substrate 42; a green light-emitting element that has a reverse-order stack structure including a green light-emitting layer containing quantum dots treated with a reducing agent; a blue light-emitting element that has a reverse-order stack structure including a blue light-emitting layer containing quantum dots treated with a reducing agent; or a light-emitting element that has a reverse-order stack structure including a light-emitting layer for another color containing quantum dots treated with a reducing agent.

In addition, in the above-described light-emitting element that has a forward-order stack structure, there may be further provided a hole injection layer between the first electrode 22, which is an anode, and the hole transport layer 23, and there may be further provided an electron injection layer between the electron transport layer 27 and the second electrode 28, which is a cathode. Furthermore, in the above-described light-emitting element that has a forward-order stack structure, either one or both of the hole transport layer 23 and the electron transport layer 27 may be omitted.

In addition, in the above-described light-emitting element that has a reverse-order stack structure, there may be further provided an electron injection layer between the first electrode 22, which is a cathode, and the electron transport layer 27, and there may be further provided a hole injection layer between the hole transport layer 23 and the second electrode 28, which is an anode. Furthermore, in the above-described light-emitting element that has a reverse-order stack structure, either one or both of the hole transport layer 23 and the electron transport layer 27 may be omitted.

The red light-emitting element 30R shown in (e) of FIG. 1 may be either a top-emission light-emitting element in which the first electrode 22, which is an anode, is made of an electrode material that is reflective to visible light, and the second electrode 28, which is a cathode, is made of an electrode material that is transmissive to visible light, so as to emit light through the second electrode 28, which is an upper electrode or a bottom-emission light-emitting element in which the first electrode 22, which is an anode, is made of an electrode material that is transmissive to visible light, and the second electrode 28, which is a cathode, is made of an electrode material that is reflective to visible light, so as to emit light through the substrate 42, which is a lower electrode.

The electrode material that is reflective to visible light may be any electrically conductive material that is reflective to visible light and may be, for example: a metal material such as Al, Mg, Li, or Ag; an alloy of these metal materials; a stack of any of the metal materials and a transparent metal oxide (e.g., indium tin oxide, indium zinc oxide, or indium gallium zinc oxide); or a stack of any of these alloys and any of the transparent metal oxides.

Meanwhile, the electrode material that is transmissive to visible light may be any electrically conductive material that is transmissive to visible light and may be, for example: a thin film of a metal material such as a transparent metal oxide (e.g., indium tin oxide, indium zinc oxide, or indium gallium zinc oxide), Al, Mg, Li, or Ag; or an electrically conductive nanomaterial such as a silver nanowire or a carbon nanotube.

The substrate 42 may be either a resin substrate composed of a resin material such as a polyimide or a glass substrate.

The hole transport layer 23 may be made of any hole transport material capable of transporting the holes injected from the first electrode 22, which is an anode, into the red light-emitting layer 25R. Among other examples, the hole transport material preferably exhibits high hole mobility. Examples include TFB (ADS), which is merely illustrative. Furthermore, the hole transport material is preferably capable of preventing the electrons transported from the second electrode 28, which is a cathode, from passing through (electron blocking material). This particular structure enables increasing the recombination efficiency for holes and electrons in the red light-emitting layer 25R.

The hole injection layer (not shown) may be made of any hole injection material capable of stabilizing the injection of holes into the red light-emitting layer 25R. Examples include PEDOT, which is merely illustrative.

The electron transport layer 27 may be made of any electron transport material capable of transporting the electrons injected from the second electrode 28, which is a cathode, into the red light-emitting layer 25R. Among other examples, the electron transport material preferably exhibits high electron mobility. Examples include ZnMgO, which is merely illustrative. Furthermore, the electron transport material is preferably capable of preventing the holes transported from the first electrode 22, which is an anode, from passing through (hole blocking material). This particular structure enables increasing the recombination efficiency of holes and electrons in the red light-emitting layer 25R.

The electron injection layer (not shown) may be made of any electron injection material capable of stabilizing the injection of electrons into the red light-emitting layer 25R.

The film formation step of forming the red light-emitting layer 25R containing quantum dots treated with a reducing agent, the step being a part of a step of forming the red light-emitting element 30R in accordance with Embodiment 1 includes: a light-emitting layer formation step shown in (a) of FIG. 1 of forming the red light-emitting layer 24R containing quantum dots that are yet to be treated with a reducing agent; a light-emitting layer processing step shown in (b) of FIG. 1 of treating the quantum dots contained in the red light-emitting layer 24R with a treating agent 51 containing a reducing agent, the step being performed after the light-emitting layer formation step shown in (a) of FIG. 1; and a rinsing step of rinsing off an excess of the reducing agent shown in (c) of FIG. 1, the step being performed after the light-emitting layer processing step shown in (b) of FIG. 1. After the rinsing step of rinsing off an excess of the reducing agent shown in (c) of FIG. 1, the red light-emitting layer 25R containing quantum dots treated with the reducing agent can be obtained as shown in (d) of FIG. 1.

The present embodiment discusses an example in which the film formation step of forming the red light-emitting layer 25R containing quantum dots treated with a reducing agent includes a rinsing step of rinsing off an excess of the reducing agent shown in (c) of FIG. 1, which is merely illustrative. Alternatively, for example, when there is not much excess reducing agent, the rinsing step of rinsing off an excess of the reducing agent shown in (c) of FIG. 1 may be omitted where appropriate.

In the light-emitting layer formation step of forming the red light-emitting layer 24R containing quantum dots that are yet to be treated with a reducing agent shown in (a) of FIG. 1, the red light-emitting layer 24R containing quantum dots that are yet to be treated with a reducing agent is formed on the hole transport layer 23 with the first electrode 22, which is an anode, and the hole transport layer 23 being stacked on the substrate 42 in this order when viewed from the substrate 42. The red light-emitting layer 24R containing quantum dots that are yet to be treated with a reducing agent is formed by applying a quantum-dot-dispersed solution containing a medium and quantum dots that are yet to be treated with a reducing agent onto the hole transport layer 23 using, for example, a spin coater, a slit coater, an inkjet printing device, or a stamp in a nitrogen environment, which is an inert gas atmosphere and also removing the medium. Thereafter, the red light-emitting layer 24R containing quantum dots that are yet to be treated with a reducing agent formed on the hole transport layer 23 is exposed to an ambient environment for 1 hour in a typical step (not shown) performed in an ambient environment before the light-emitting layer processing step shown in (b) of FIG. 1. The typical step performed in an ambient environment before the light-emitting layer processing step refers to, for example, a resist agent application step and exposure, development, and drying steps performed in a typical individual-coating step by lift-off. These steps are generally often performed in an ambient environment. The present embodiment discusses an example in which after performing the light-emitting layer formation step of forming the red light-emitting layer 24R containing quantum dots that are yet to be treated with a reducing agent shown in (a) of FIG. 1 including the above-described application step and the above-described medium removal step in a nitrogen environment, the red light-emitting layer 24R formed on the hole transport layer 23 in a typical step (not shown) performed in an ambient environment before the light-emitting layer processing step shown in (b) of FIG. 1 is simply exposed to an ambient environment for 1 hour, which is merely illustrative. Alternatively, for example, the light-emitting layer formation step of forming the red light-emitting layer 24R containing quantum dots that are yet to be treated with a reducing agent shown in (a) of FIG. 1 including the above-described application step and the above-described medium removal step may be performed in an ambient environment. In addition, the duration of the exposure to an ambient environment of the red light-emitting layer 24R containing quantum dots that are yet to be treated with a reducing agent formed on the hole transport layer 23 in a typical step (not shown) performed in an ambient environment before the light-emitting layer processing step shown in (b) of FIG. 1 may be shorter than 1 hour and may be longer than 1 hour. Additionally, steps may be performed of, for example, applying a resist agent, exposure, development, and drying.

The red light-emitting layer 24R containing quantum dots that are yet to be treated with a reducing agent shown in (a) of FIG. 1 needs only to have such a thickness that the red light-emitting layer 25R containing quantum dots treated with a reducing agent shown in (d) of FIG. 1 after being subjected to the light-emitting layer processing step shown in (b) of FIG. 1 and the rinsing step of rinsing off an excess of the reducing agent shown in (c) of FIG. 1 can achieve a good charge-carrier balance between holes and electrons. If the red light-emitting layer 25R is too thin, the film could have pinholes, possibly leading to leaks; and if the red light-emitting layer 25R is too thick, it becomes difficult to inject carriers, possibly leading to deterioration in luminescence properties. Therefore, the red light-emitting layer 25R containing quantum dots treated with a reducing agent shown in (d) of FIG. 1 preferably has a thickness of from 5 nm to 100 nm, both inclusive, more preferably from 10 nm to 30 nm, both inclusive. Since the thickness of the red light-emitting layer 24R containing quantum dots that are yet to be treated with a reducing agent is controlled through a combination of, for example, the concentration of the quantum-dot-dispersed solution, the spin rate of the spin coater, and the boiling point of the medium contained in the quantum-dot-dispersed solution, the concentration of the quantum-dot-dispersed solution may be specified in a suitable manner and is preferably from 1 mg/mL to 100 mg/mL, both inclusive, and more preferably from 5 mg/mL to 30 mg/mL, both inclusive. A quantum-dot-dispersed solution with a concentration of 20 mg/ml is used in the present embodiment. As described above, since the thickness of the red light-emitting layer 24R containing quantum dots that are yet to be treated with a reducing agent is controlled through a combination of, for example, the concentration of the quantum-dot-dispersed solution, the spin rate of the spin coater, and the boiling point of the medium contained in the quantum-dot-dispersed solution, the spin rate may be specified in a suitable manner when the quantum-dot-dispersed solution is applied using a spin coater. If the spin rate is too slow, the film could become inconsistent depending on, for example, the boiling point and viscosity of the quantum-dot-dispersed solution; if the spin rate is too fast, the cover rate of the film could fall. Therefore, the quantum-dot-dispersed solution is preferably applied with a spin rate of preferably from 1,000 rpm to 5,000 rpm, both inclusive and more preferably from 2,000 rpm to 4,000 rpm, both inclusive. In the present embodiment, the red light-emitting layer 24R containing quantum dots that are yet to be treated with a reducing agent is applied by spinning the spin coater at a spin rate of 2,000 rpm for 40 seconds. If a baking step is performed, the baking step can be done using, for example, a hotplate. The heat-treatment temperature is not limited in any particular manner so long as the temperature does not adversely affect, for example, the substrate 42, the first electrode 22, the hole transport layer 23, and the red light-emitting layer 24R. The heat treatment is preferably performed at a temperature of from 40° C. to 200° C., both inclusive, and more preferably from 60° C. to 120° C., both inclusive. Note that the baking step may be performed, for example, either in a nitrogen environment, which is an inert gas atmosphere, or in an ambient environment.

The quantum dots QD that are yet to be treated with a reducing agent contained in the red light-emitting layer 24R shown in (a) of FIG. 1 and (a) of FIG. 2 may have, for example, a core structure, a core/shell structure, a core/shell/shell structure, or a core/continuously-changing-ratio shell structure. The present embodiment, as shown in (a) of FIG. 2, discusses an example in which the quantum dots QD are used that have a core/shell structure including an InP core CO portion and a ZnS shell SH portion, which is merely illustrative. Alternatively, for example, the quantum dots QD may have a core/shell structure including an CdSe core CO portion and a ZnS shell SH portion, a core/shell structure including a ZnSe core CO portion and a ZnS shell SH portion, or a core/shell structure including a ZnTe core CO portion and a ZnSe shell SH portion. As described above, the present embodiment discusses an example in which the core CO portion is binary, which is merely illustrative. Alternatively, for example, the core CO portion may be, for example, single, ternary, or quaternary. In addition, as described above, the present embodiment discusses an example in which the shell SH portion is binary, which is merely illustrative. Alternatively, for example, the shell SH portion may be, for example, single or ternary and may be a shell with a continuously changing composition ratio. Furthermore, as shown in (a) of FIG. 2, there may be provided ligands Lig on the surface of the quantum dots QD. The ligands Lig may be either organic or inorganic.

Note that when, for example, a step of exposing, to the atmosphere, the red light-emitting layer 24R containing quantum dots that are yet to be treated with a reducing agent, like a typical step (not shown) performed in an ambient environment before the above-described light-emitting layer processing step shown in (b) of FIG. 1, is included before the light-emitting layer processing step shown in (b) of FIG. 1, the internal quantum yield of the quantum dots QD decreases due to the effect of the, for example, OH^{—} groups and O₂^{—} groups provided on the surface of the quantum dots QD due to adsorption of, for example, water and oxygen to the quantum dots QD as shown in (a) of FIG. 2. These problems may be addressed by performing, in an inert gas atmosphere, for example, in a nitrogen atmosphere, the above-described typical step performed in an ambient environment. To perform such a step in an inert gas atmosphere, however, large-sized and costly manufacturing equipment is required, which causes another problem of additional manufacturing cost.

In the present embodiment, in the film formation step of forming the red light-emitting layer 25R containing quantum dots treated with a reducing agent shown in (d) of FIG. 1, the steps that are performed after the above-described application step and the above-described medium removal step for the quantum-dot-dispersed solution, in other words, the typical step (not shown) performed in an ambient environment before the above-described light-emitting layer processing step shown in (b) of FIG. 1, the light-emitting layer processing step shown in (b) of FIG. 1, and the rinsing step of rinsing off an excess of the reducing agent shown in (c) of FIG. 1 are all performed in an ambient environment. The present embodiment can therefore streamline manufacturing equipment and reduce manufacturing cost. If the application step of applying the quantum-dot-dispersed solution is also performed in an ambient environment, the present embodiment can further streamline manufacturing equipment and reduce manufacturing cost.

In the light-emitting layer processing step shown in (b) of FIG. 1, as described above, the quantum dots QD contained in the red light-emitting layer 24R and having a reduced internal quantum yield are treated with the treating agent 51 containing a reducing agent. In this step, by bringing the reducing agent contained in the treating agent 51 into contact with the quantum dots QD contained in the red light-emitting layer 24R and having a reduced internal quantum yield, as shown in (b) of FIG. 2, for example, OH^{—} groups and O₂^{—} groups, which are a cause of the reduced internal quantum yield of the quantum dots QD, are removed, thereby obtaining the red light-emitting layer 25R containing the quantum dots QD with an improved internal quantum yield.

The present embodiment discusses an example in which the treating agent 51 contains sodium borohydride (NaBH₄) as the reducing agent, which is merely illustrative. Alternatively, the treating agent 51 may contain, as the reducing agent, at least one of sodium borohydride (NaBH₄), lithium borohydride (LiBH₄), and lithium aluminum hydride (LiAlH₄). Furthermore, the treating agent 51 may contain, as the reducing agent, for example, at least one of sodium borohydride (NaBH₄), lithium borohydride (LiBH₄), lithium aluminum hydride (LiAlH₄), hydrazine, hydrogen, hydrogen sulfide, and ammonia.

As described in the foregoing, in the present embodiment, the light-emitting layer processing step of treating the quantum dots QD contained in the red light-emitting layer 24R with the treating agent 51 containing the reducing agent shown in (b) of FIG. 1 is performed after the light-emitting layer formation step shown in (a) of FIG. 1. Therefore, for example, even if the quantum dots QD have been degraded by the adverse effects of, for example, oxygen and water contained in the atmosphere before the light-emitting layer processing step shown in (b) of FIG. 1, the present embodiment can improve the properties of the degraded quantum dots QD after the light-emitting layer processing step shown in (b) of FIG. 1.

In the present embodiment, the treating agent 51 contains, as the reducing agent, sodium borohydride (NaBH₄), and the reducing agent contained in the treating agent 51 contains an element (Na (electronegativity: 0.93)) that has a lower electronegativity than all the elements contained in the quantum dots QD (In (electronegativity: 1.78), P (electronegativity: 2.19), Zn (electronegativity: 1.65), and S (electronegativity: 2.58)). As described in the foregoing, since the quantum dots QD contained in the red light-emitting layer 24R are treated with a reducing agent containing an element that has a lower electronegativity than all the elements contained in the quantum dots QD, the quantum dots QD can be efficiently reduced.

As described in the foregoing, in view of efficiently reducing the quantum dots QD, the treating agent 51 preferably contains, as the reducing agent, at least one of sodium borohydride (NaBH₄), lithium borohydride (LiBH₄), and lithium aluminum hydride (LiAlH₄), which is merely illustrative. Alternatively, the element contained in the reducing agent in the treating agent 51 and also having a lower electronegativity than all the elements contained in the quantum dots QD is preferably an element having an electronegativity less than or equal to the electronegativity of aluminum (Al (electronegativity: 1.61)). Suitably used examples of the element having an electronegativity less than or equal to the electronegativity of aluminum include Al, Li, and Na. In addition, the element contained in the reducing agent in the treating agent 51 and also having a lower electronegativity than all the elements contained in the quantum dots QD is more preferably an element having an electronegativity less than or equal to the electronegativity of lithium (Li (electronegativity: 0.98)). Suitably used examples of the element having an electronegativity less than or equal to the electronegativity of lithium include Li and Na. In addition, the element contained in the reducing agent in the treating agent 51 and also having a lower electronegativity than all the elements contained in the quantum dots QD is more preferably an element having an electronegativity less than or equal to the electronegativity of sodium (Na (electronegativity: 0.93)). Suitably used examples of the element having an electronegativity less than or equal to the electronegativity of sodium include Na.

The treating agent 51 shown in (b) of FIG. 1 contains a reducing agent and a medium. In the present embodiment, the treating agent 51 contains sodium borohydride (NaBH4) as the reducing agent and methanol as the medium. The medium is not limited in any particular manner so long as the medium can dissolve the reducing agent, but does not dissolve the quantum dots QD contained in the red light-emitting layer 24R. In the present embodiment, to dissolve sodium borohydride (NaBH₄), which is the reducing agent, methanol is used, but ethanol may be used. Methanol has a higher saturation solubility to sodium borohydride (NaBH₄), hence a higher degree of freedom in solution concentration, than ethanol. When the reducing agent is a material other than sodium borohydride (NaBH₄), a medium that can dissolve the reducing agent, but does not dissolve the quantum dots QD contained in the red light-emitting layer 24R needs only to be selected in a suitable manner.

A decrease in the concentration of the treating agent 51 containing a reducing agent and a medium causes a decrease in the frequency at which the quantum dots QD contained in the red light-emitting layer 24R come into contact with the reducing agent, which leads to a decrease in expected effects. On the other hand, an increase in the concentration of the treating agent 51 containing a reducing agent and a medium causes an increase in the frequency at which the quantum dots QD contained in the red light-emitting layer 24R come into contact with the reducing agent, which leads to an increase in expected effects, but makes it difficult to remove excess reducing agent. If the reducing agent remains in excess in the red light-emitting layer 24R, the flatness and smoothness of the surface of the red light-emitting layer 24R could fall, and for this reason, the excess reducing agent is preferably removed in the rinsing step (detailed later). In the present embodiment, the treating agent 51 is described as having a concentration of 0.53 mol/L (20 mg/mL), which is merely illustrative. Alternatively, the treating agent 51 preferably has a concentration of from 0.01 mol/L to 2.0 mol/L, both inclusive, and more preferably from 0.1 mol/L to 1 mol/L, both inclusive.

In the present embodiment, the red light-emitting layer 24R is treated with the treating agent 51 by spinning a spin coater at a spin rate of 3,000 rpm for 60 seconds, for example, 10 seconds after the treating agent 51 is dispensed dropwise to the red light-emitting layer 24R.

Thereafter, in the rinsing step of rinsing off excess reducing agent shown in (c) of FIG. 1, if the treating agent 51 dries, the dissolution rate of the excess reducing agent in the rinsing medium decreases, and the removing efficiency for the excess reducing agent decreases when compared with other treatments under the same conditions. Therefore, the rinsing step is preferably performed before the treating agent 51 dries, immediately after the red light-emitting layer 24R is treated with the treating agent 51. In the present embodiment, the substrate 42 containing the red light-emitting layer 24R treated with the treating agent 51 shown in (b) of FIG. 1 is immediately immersed in methanol by shaking for 30 seconds before the treating agent 51 dries. Note that although a longer immersion time results in a higher removal ratio for the excess reducing agent, for example, there may be adverse effects on the members other than the red light-emitting layer 24R, and the ligands Lig on the surface of the quantum dots QD may come off. Therefore, the immersion time is preferably from 10 seconds to 180 seconds, both inclusive, and more preferably from 30 seconds to 90 seconds, both inclusive. The rinsing medium may be, for example, ethanol apart from methanol. However, since methanol has a higher saturation solubility to sodium borohydride (NaBH₄) than ethanol, and methanol hence exhibits a higher capability to dissolve the excess reducing agent, methanol is used as the, rinsing medium in the present embodiment. Thereafter, at least one of a medium removal step using a nitrogen gun, a centrifugal medium removal step using a spin coater, and a medium removal step using a hotplate may be performed if necessary, to remove the rinsing medium. Note that in the centrifugal medium removal step using a spin coater, the spin rate of the spin coater is preferably from 1,000 rpm to 5,000 rpm, both inclusive, and more preferably from 2,000 rpm to 4,000 rpm, both inclusive. In addition, in a medium removal step using a hotplate, the heat-treatment temperature is not limited in any particular manner so long as the temperature does not adversely affect the substrate 42, the first electrode 22, the hole transport layer 23, and the red light-emitting layer 25R. The heat-treatment temperature is preferably from 40° C. to 200° C., both inclusive, and more preferably from 60° C. to 120° C., both inclusive. In the above-described rinsing step, the excess of the reducing agent is removed by rinsing off; therefore, the above-described rinsing step can restrain the red light-emitting layer 25R from being adversely affected by the remaining excess of the reducing agent. Examples of the adverse effects that can be caused by the excess of the reducing agent on the red light-emitting layer 25R include reduced flatness and smoothness of, and non-uniform emission of light by, the red light-emitting layer 25R due to the residual excess of the reducing agent.

In addition, after the above-described rinsing step, it was verified by the following method that an element contained in the reducing agent and also having a lower electronegativity than all the elements contained in the quantum dots QD remained on the surface of the quantum dots QD in a quantity of from 10 to 100, both inclusive, per quantum dot QD. In the present embodiment, it was verified that elemental Na remained on the surface of the quantum dots QD in a quantity of from 10 to 100, both inclusive, per quantum dot QD.

The verification can be done by calculating the number of each element per quantum dot QD including elements remaining on the surface of the quantum dots QD from results of TEM measurement and further calculating the number of the element contained in the reducing agent and also having a lower electronegativity than all the elements contained in the quantum dots QD from the calculated numbers.

As described in the foregoing, if an element contained in the reducing agent and also having a lower electronegativity than all the elements contained in the quantum dots QD remains on the surface of the quantum dots QD in a quantity of from 10 to 100, both inclusive, per quantum dot QD after the above-described rinsing step, the red light-emitting layer 25R can be restrained from adverse effects which could otherwise caused by the remaining element in the post-process.

As described in the foregoing, the present embodiment discusses an example in which after the treating agent 51 is dispensed dropwise to the red light-emitting layer 24R, the red light-emitting layer 24R is treated with the treating agent 51 by spinning the spin coater, which is merely illustrative. Alternatively, the red light-emitting layer 24R may be treated with the treating agent 51 by immersion, and the red light-emitting layer 24R may be treated with the treating agent 51 by dispersion. Even if the red light-emitting layer 24R is treated with the treating agent 51 by, for example, immersion or dispersion, for example, the rinsing step and the medium removal step for an excess of the reducing agent shown in (c) of FIG. 1 can be still performed as described above.

The present embodiment discusses an example in which the red light-emitting layer 24R is treated with the treating agent 51 containing a reducing agent and a medium in the light-emitting layer processing step shown in (b) of FIG. 1, which is merely illustrative. Alternatively, the treating agent 51 may contain a reducing agent, a medium, and ligands. The use of such a treating agent containing a reducing agent, a medium, and ligands enables bringing the quantum dots QD contained in the red light-emitting layer 24R into contact with the reducing agent and the ligands. In addition, the step of treating the quantum dots QD contained in the red light-emitting layer 24R with a reducing agent and the step of treating the quantum dots QD contained in the red light-emitting layer 24R with ligands can be performed in a single step.

In addition, as in Embodiment 3 (detailed later), a ligand-modification step of bringing the ligands into contact with the quantum dots QD contained in the red light-emitting layer 25R may be performed after the light-emitting layer processing step shown in (b) of FIG. 1. In such a case, since the ligand-modification step is additionally performed after the light-emitting layer processing step shown in (b) of FIG. 1, the properties of the quantum dots QD contained in the red light-emitting layer 25R can be further improved.

Furthermore, the ligand-modification step of bringing the ligands and the quantum dots QD contained in the red light-emitting layer 24R into contact with each other may be performed between the light-emitting layer formation step shown in (a) of FIG. 1 and the light-emitting layer processing step shown in (b) of FIG. 1. In such a case, the properties of the quantum dots QD contained in the red light-emitting layer 24R can also be improved.

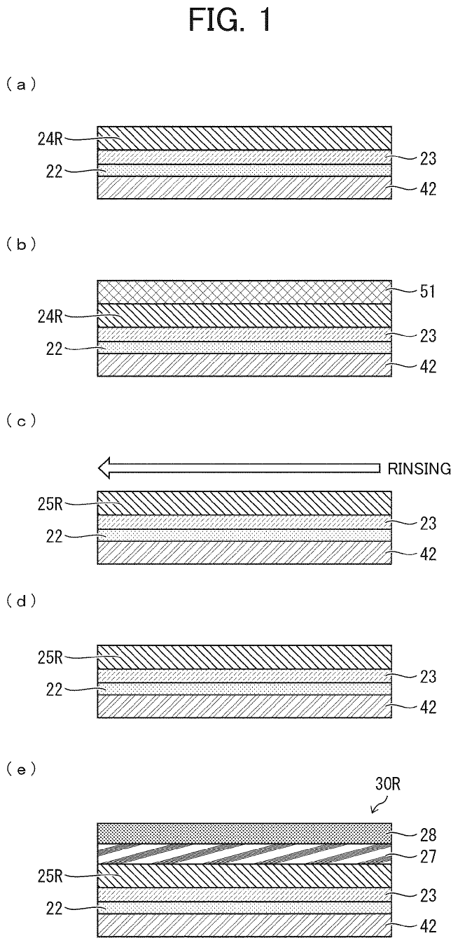

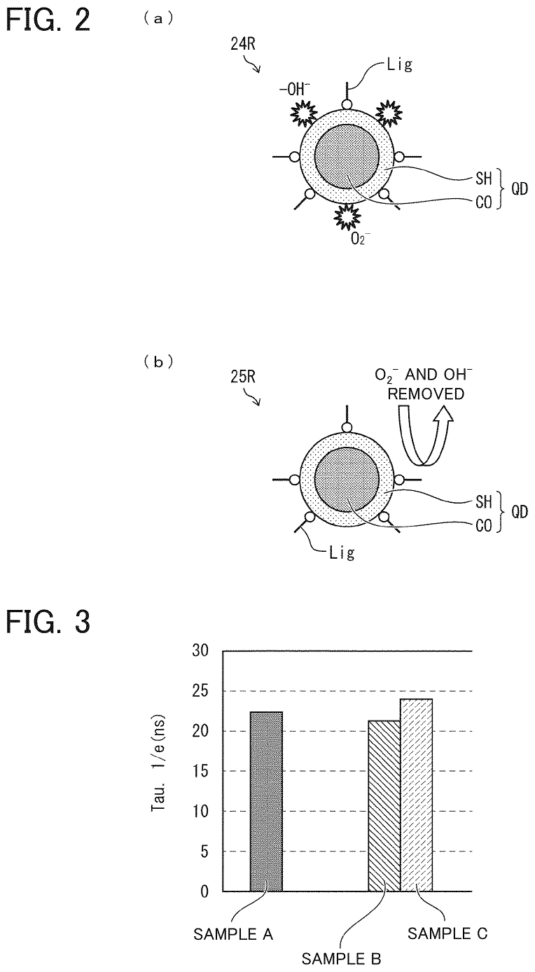

FIG. 3 is a diagram representing: the fluorescence lifetime of a light-emitting layer (sample A) formed by coating and medium removal in a nitrogen environment; the fluorescence lifetime of a light-emitting layer (sample B) obtained by additionally exposing the light-emitting layer (sample A) in an ambient environment for 1 hour; and the fluorescence lifetime of a light-emitting layer (sample C) obtained by additionally performing a light-emitting layer processing step shown in (b) of FIG. 1 on the light-emitting layer (sample B). Note that the light-emitting layer (sample B) obtained by additionally exposing the light-emitting layer (sample A) in an ambient environment for 1 hour and the light-emitting layer (sample C) obtained by additionally performing a light-emitting layer processing step shown in (b) of FIG. 1 on the light-emitting layer (sample B) were prepared because after the light-emitting layer (sample A) was formed by coating and medium removal in a nitrogen environment, it was verified how much the degraded properties of the quantum dots QD adversely affected in the various steps performed in an ambient environment (e.g., a typical step (not shown) performed in an ambient environment before the light-emitting layer processing step shown in the above-described (b) of FIG. 1) could be recovered.

The results of fluorescence lifetime shown in FIG. 3 are results of measurement on the light-emitting layer (sample A), the light-emitting layer (sample B), and the light-emitting layer (sample C) provided between the glass substrate and the sealing glass and caused to fluoresce (photoluminescence or PL) under the same excitation light.

The fluorescence lifetime of the light-emitting layer (sample B) obtained by forming a light-emitting layer (sample A) by coating and medium removal in a nitrogen environment and additionally exposing the light-emitting layer (sample A) in an ambient environment for 1 hour is much shorter than the fluorescence lifetime of the light-emitting layer (sample A) formed by coating and medium removal in a nitrogen environment. This is because, as described above, the quantum dots QD contained in the light-emitting layer are adversely affected by, for example, the OH^{—} groups and the O₂^{—} groups on the surface of the quantum dots QD due to the adsorption of, for example, water and oxygen during the 1-hour exposure to the atmosphere. Accordingly, in the present embodiment, by treating, with a treating agent containing a reducing agent, the quantum dots QD contained in the light-emitting layer exposed to the atmosphere for 1 hour, even if the fluorescence lifetime of the quantum dots QD is significantly shortened, for example, under the adverse effects of oxygen and water in the atmosphere, the fluorescence lifetime of the quantum dots QD can be significantly improved as is the case with the light-emitting layer (sample C) shown in FIG. 3. The effects of significantly improving the fluorescence lifetime of the resultant quantum dots QD by treating the quantum dots QD exposed to the atmosphere with a treating agent containing a reducing agent can be achieved similarly when the quantum dots QD obtained by performing the entire light-emitting layer formation step, in other words, an application step of applying a quantum-dot-dispersed solution and a step of removing the medium, in an ambient environment are treated with a treating agent containing a reducing agent.

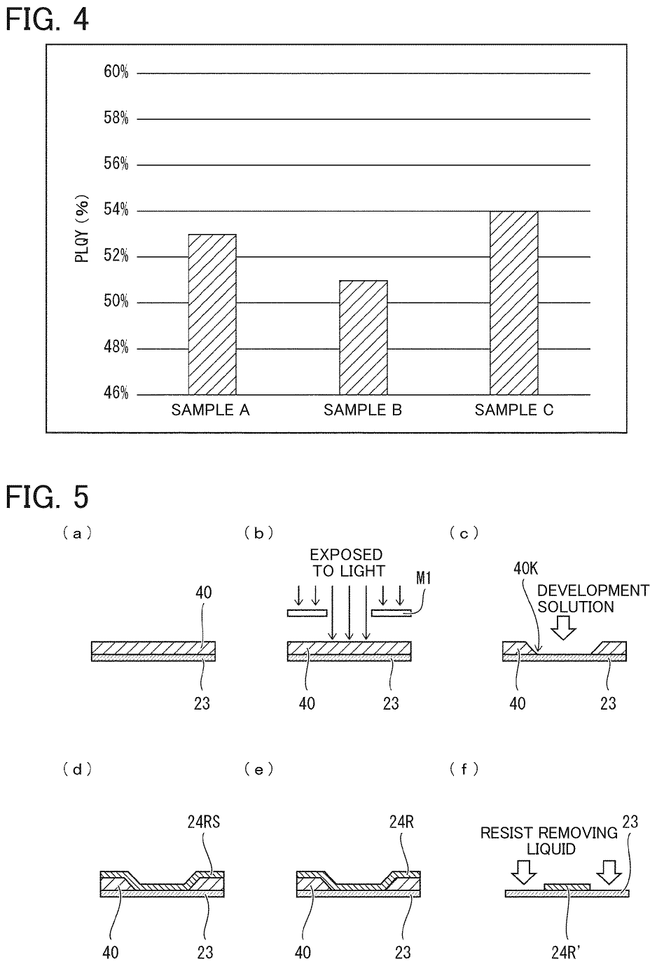

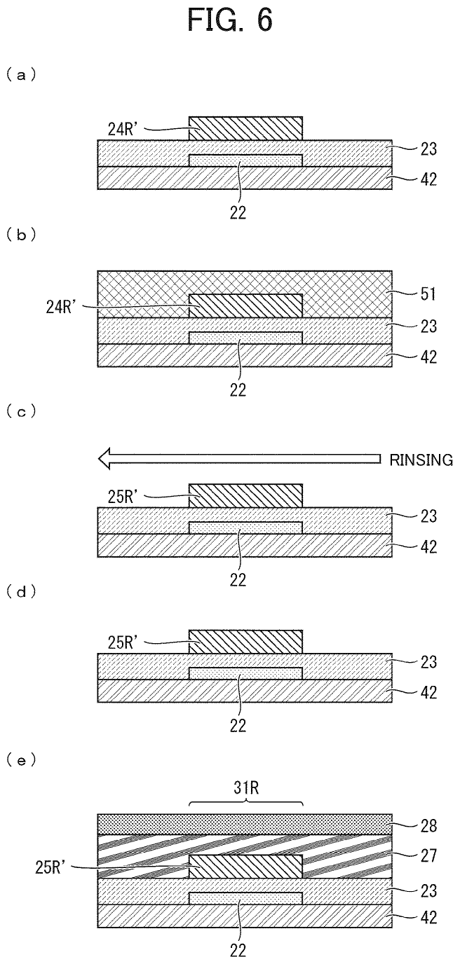

FIG. 4 is a diagram representing the internal quantum yield of the quantum dots contained in the light-emitting layer (sample A) shown in FIG. 3, the internal quantum yield of the quantum dots contained in the light-emitting layer (sample B) shown in FIG. 3, and the internal quantum yield of the quantum dots contained in the light-emitting layer (sample C) shown in FIG. 3.

The internal quantum yield (PLQY: photoluminescence quantum yield) of the light-emitting layer (sample B) obtained by additionally exposing, in an ambient environment for 1 hour, the light-emitting layer (sample A) formed by coating and medium removal in a nitrogen environment is much lower than the internal quantum yield of the light-emitting layer (sample A) formed by coating and medium removal in a nitrogen environment. This is because, as described above, the quantum dots QD contained in the light-emitting layer are adversely affected by, for example, the OH^{—} groups and the O₂^{—} groups on the surface of the quantum dots QD due to the adsorption of, for example, water and oxygen during the 1-hour exposure to the atmosphere. Accordingly, in the present embodiment, by treating, with a treating agent containing a reducing agent, the quantum dots QD contained in the light-emitting layer exposed to the atmosphere, even if the internal quantum yield of the quantum dots QD adversely affected by, for example, oxygen and water contained in the atmosphere has significantly decreased, the internal quantum yield of the quantum dots QD can be significantly improved as is the case with the light-emitting layer (sample C) shown in FIG. 4. The effects of significantly improving the internal quantum yield of the resultant quantum dots QD by treating the quantum dots QD exposed to the atmosphere with a treating agent containing a reducing agent can be achieved similarly when the quantum dots QD obtained by performing the entire light-emitting layer formation step, in other words, an application step of applying a quantum-dot-dispersed solution and a step of removing the medium, in an ambient environment are treated with a treating agent containing a reducing agent.

### Embodiment 2

A description is given next of Embodiment 2 of the disclosure with reference to FIGS. 5 to 7. A red light-emitting element 31R in accordance with the present embodiment differs from above-described Embodiment 1 in that the red light-emitting element 31R includes a red light-emitting layer 25R′ patterned by lift-off. Embodiment 2 is otherwise as described in Embodiment 1. For convenience of description, members of the present embodiment that have the same function as members shown in the drawings for Embodiment 1 above are indicated by the same reference numerals, and description thereof is omitted.

The present embodiment discusses, as an example, the red light-emitting element 31R that has a forward-order stack structure including a stack of a first electrode 22, which is an anode, a hole transport layer 23, the red light-emitting layer 25R′ containing quantum dots treated with a reducing agent and also patterned by lift-off, an electron transport layer 27, and a second electrode 28, which is a cathode, all of which are provided on a substrate 42 in this order when viewed from the substrate 42 as shown in (e) of FIG. 6, which is merely illustrative. Alternatively, the present embodiment may be applied to, for example: a green light-emitting element that has a forward-order stack structure including a green light-emitting layer containing quantum dots treated with a reducing agent and also patterned by lift-off, a blue light-emitting element that has a forward-order stack structure including a blue light-emitting layer containing quantum dots treated with a reducing agent and also patterned by lift-off; or a light-emitting element that has a forward-order stack structure including a light-emitting layer for another color containing quantum dots treated with a reducing agent and also patterned by lift-off. As further alternative examples (not show), the present embodiment may be applied to: a red light-emitting element that has a reverse-order stack structure including a stack of the first electrode 22, which is a cathode, the electron transport layer 27, the red light-emitting layer 25R′ containing quantum dots treated with a reducing agent and also patterned by lift-off, the hole transport layer 23, which is an anode, and the second electrode 28, all of which are provided on the substrate 42 in this order when viewed from the substrate 42; a green light-emitting element that has a reverse-order stack structure including a green light-emitting layer containing quantum dots treated with a reducing agent and also patterned by lift-off; a blue light-emitting element that has a reverse-order stack structure including a blue light-emitting layer containing quantum dots treated with a reducing agent and also patterned by lift-off; or a light-emitting element that has a reverse-order stack structure including a light-emitting layer for another color containing quantum dots treated with a reducing agent and also patterned by lift-off.

Portions (a) of FIG. 5, (b) of FIG. 5, (c) of FIG. 5, (d) of FIG. 5, (e) of FIG. 5, and (f) of FIG. 5 are diagrams illustrating a patterning step for a red light-emitting layer 24R′ by lift-off that is a part of steps of forming the red light-emitting element 31R in accordance with Embodiment 2.

The patterning step for the red light-emitting layer 24R′ by lift-off includes: a step of forming a resist layer 40 on the hole transport layer 23 shown in (a) of FIG. 5; a step of exposing to light the resist layer 40 via a mask M1 shown in (b) of FIG. 5; a step of developing using a development solution shown in (c) of FIG. 5 to form an opening 40K through the resist layer 40; an application step of applying a solution 24RS containing quantum dots shown in (d) of FIG. 5; a step of obtaining the red light-emitting layer 24R containing quantum dots by heat treatment of the solution 24RS containing quantum dots shown in (e) of FIG. 5; and a step of obtaining the patterned red light-emitting layer 24R′ by removing the resist layer 40 using a resist removing liquid shown in (f) of FIG. 5. Note that the resist removing liquid shown in (f) of FIG. 5 may be, for example, PGMEA, which is merely illustrative.

Note that if the step, performed in an ambient environment, of obtaining the red light-emitting layer 24R containing quantum dots by heat treatment of the solution 24RS containing quantum dots shown in (e) of FIG. 5 and the step of obtaining the patterned red light-emitting layer 24R′ by removing the resist layer 40 using a resist removing liquid shown in (f) of FIG. 5 are involved after the application step of applying the solution 24RS containing quantum dots shown in (d) of FIG. 5, but before the light-emitting layer processing step shown in (b) of FIG. 6, the quantum dots QD are adversely affected by, for example, the OH^{—} groups and the O₂^{—} groups on the surface of the quantum dots QD due to the adsorption of, for example, water and oxygen and further adversely affected during the removal of the resist layer using the resist removing liquid. These problems may be addressed by performing, in an inert gas atmosphere, for example, in a nitrogen atmosphere, the steps shown in (e) of FIG. 5 and (f) of FIG. 5. To perform such steps in an inert gas atmosphere, however, large-sized and costly manufacturing equipment is required, which causes another problem of additional manufacturing cost.

In the present embodiment, only the application step of applying the solution 24RS containing quantum dots shown in (d) of FIG. 5 is performed in a nitrogen environment, and the steps shown in (a) of FIG. 5 to (c) of FIG. 5, (e) of FIG. 5, (f) of FIG. 5, and (a) of FIG. 6 to (e) of FIG. 6 (detailed later) are performed in an ambient environment. The present embodiment can therefore streamline manufacturing equipment and reduce manufacturing cost. Alternatively, the application step of applying the solution 24RS containing quantum dots shown in (d) of FIG. 5 may also be performed in an ambient environment, which enables further streamlining manufacturing equipment and reducing manufacturing cost.

Portions (a) of FIG. 6, (b) of FIG. 6, (c) of FIG. 6, (d) of FIG. 6, and (e) of FIG. 6 are diagrams illustrating steps of forming the red light-emitting element 31R in accordance with Embodiment 2, including film formation steps of forming a light-emitting layer including a step of treating, with a reducing agent, the quantum dots contained in the red light-emitting layer 24R′ patterned by lift-off shown in FIG. 5.

The red light-emitting layer 24R′ containing the quantum dots QD shown in (a) of FIG. 6 are the red light-emitting layer 24R′ patterned by lift-off shown in (f) of FIG. 5. The light-emitting layer processing step shown in (b) of FIG. 6 is the same as the light-emitting layer processing step shown in (b) of FIG. 1, and the rinsing step for an excess of the reducing agent shown in (c) of FIG. 6 is the same as the rinsing step for an excess of the reducing agent shown in (c) of FIG. 1. Description thereof is therefore omitted here. By performing the light-emitting layer processing step shown in (b) of FIG. 6 and the rinsing step for an excess of the reducing agent shown in (c) of FIG. 6, the red light-emitting layer 25R′ containing the quantum dots treated with a reducing agent can be obtained as shown in (d) of FIG. 6.

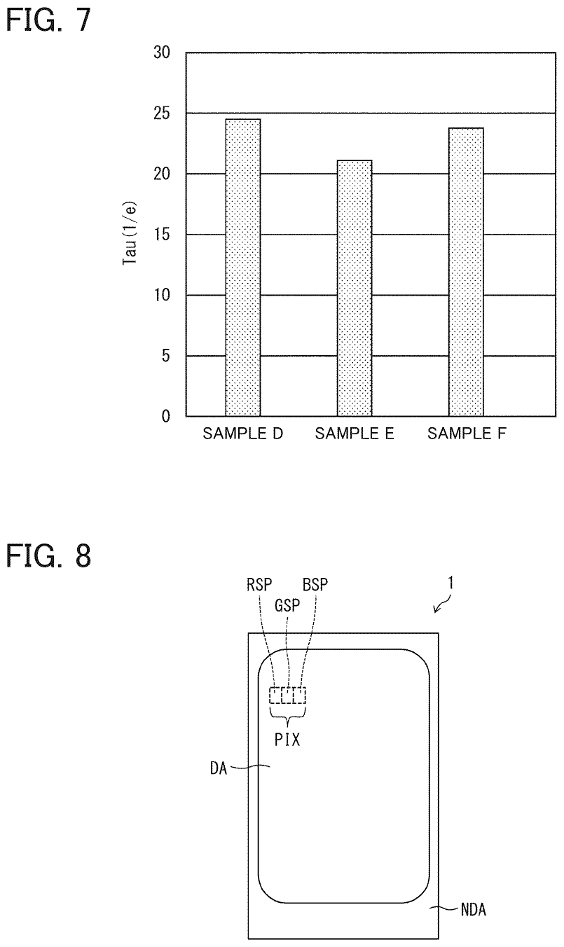

FIG. 7 is a diagram representing: the fluorescence lifetime of a light-emitting layer (sample D) formed by coating and medium removal in a nitrogen environment; the fluorescence lifetime of a light-emitting layer (sample E) subjected to a lift-off patterning step shown in FIG. 5; and the fluorescence lifetime of a light-emitting layer (sample F) obtained by additionally performing a light-emitting layer processing step shown in (b) of FIG. 6 on the light-emitting layer (sample E).

The results of fluorescence lifetime shown in FIG. 7 are results of measurement on the light-emitting layer (sample D), the light-emitting layer (sample E), and the light-emitting layer (sample F) provided between the glass substrate and the sealing glass and caused to fluoresce (photoluminescence or PL) under the same excitation light.

The fluorescence lifetime of the light-emitting layer (sample E) obtained by performing the lift-off patterning step shown in FIG. 5 is much shorter than the fluorescence lifetime of the light-emitting layer (sample D) formed by coating and medium removal in a nitrogen environment. This is because, as described above, the quantum dots QD contained in the light-emitting layer are adversely affected by, for example, the OH^{—} groups and the O₂^{—} groups on the surface of the quantum dots QD due to the adsorption of, for example, water and oxygen and further adversely affected during the removal of the resist layer using a resist removing liquid, in the step, performed in an ambient environment, of obtaining the red light-emitting layer 24R containing quantum dots by heat treatment of the solution 24RS containing quantum dots shown in (e) of FIG. 5 and in the step of obtaining the patterned red light-emitting layer 24R′ by removing the resist layer 40 using a resist removing liquid shown in (f) of FIG. 5. Accordingly, in the present embodiment, by treating, with a treating agent containing a reducing agent, the quantum dots QD contained in the light-emitting layer after those steps shown in (e) of FIG. 5 and (f) of FIG. 5, even if the fluorescence lifetime of the quantum dots QD is significantly shortened, the fluorescence lifetime of the quantum dots QD can be significantly improved as is the case with sample F shown in FIG. 7.

In addition, the internal quantum yield of the light-emitting layer (sample E) subjected to the lift-off patterning step shown in FIG. 5 is much shorter than the internal quantum yield of the light-emitting layer (sample D) formed by coating and medium removal in a nitrogen environment (not shown). This is because of the same reasons as those for the above-described shortened fluorescence lifetime. Accordingly, in the present embodiment, by treating, with a treating agent containing a reducing agent, the quantum dots QD contained in the light-emitting layer after the steps shown in (e) of FIG. 5 and (f) of FIG. 5, even if the internal quantum yield of the quantum dots QD has significantly decreased, the internal quantum yield of the quantum dots QD can be significantly improved.

The present embodiment discusses as an example, the red light-emitting layer 24R′ being treated with the treating agent 51 containing a reducing agent and a medium in the light-emitting layer processing step shown in (b) of FIG. 6, which is merely illustrative. Alternatively, the treating agent 51 may contain a reducing agent, a medium, and ligands. The use of such a treating agent containing a reducing agent, a medium, and ligands enables bringing the quantum dots QD contained in the red light-emitting layer 24R′ into contact with the reducing agent and the ligands. In addition, the step of treating the quantum dots QD contained in the red light-emitting layer 24R′ with a reducing agent and the step of treating the quantum dots QD contained in the red light-emitting layer 24R′ with ligands can be performed in a single step.

In addition, as in Embodiment 3 (detailed later), a ligand-modification step of bringing the ligands into contact with the quantum dots QD contained in the red light-emitting layer 25R′ may be performed after the light-emitting layer processing step shown in (b) of FIG. 6. In such a case, since the ligand-modification step is additionally performed after the light-emitting layer processing step shown in (b) of FIG. 6, the properties of the quantum dots QD contained in the red light-emitting layer 25R′ can be further improved.

Furthermore, the ligand-modification step of bringing the ligands and the quantum dots QD contained in the red light-emitting layer 24R′ into contact with each other may be performed between, the light-emitting layer formation step shown in (a) of FIG. 6 and the light-emitting layer processing step shown in (b) of FIG. 6. In such a case, the properties of the quantum dots QD contained in the red light-emitting layer 24R′ can also be improved.

The description has so far discussed that the treatment of the quantum dots QD contained in the light-emitting layer (sample E) with a treating agent containing a reducing agent can significantly improve the fluorescence lifetime and the internal quantum yield as is the case with the light-emitting layer (sample F). Likewise, the fluorescence lifetime and the internal quantum yield are significantly improved also when the quantum dots QD contained in the light-emitting layer in a case where the light-emitting layer formation steps shown in (a) of FIG. 5 to (f) of FIG. 5 and (a) of FIG. 6 in accordance with the present embodiment is performed in an ambient environment are treated with a treating agent containing a reducing agent.

### Embodiment 3

A description is given next of Embodiment 3 of the disclosure with reference to FIGS. 8 to 17. A display device 1 in accordance with the present embodiment differs from above-described Embodiments 1 and 2 in that the display device 1 includes: a red light-emitting layer 26R′″ containing quantum dots treated with a reducing agent and also patterned by lift-off; a green light-emitting layer 26G″ containing quantum dots treated with a reducing agent and also patterned by lift-off; and a blue light-emitting layer 26B′ containing quantum dots treated with a reducing agent and also patterned by lift-off. The display device 1 is otherwise as described in Embodiments 1 and 2. For convenience of description, members of the present embodiment that have the same function as members shown in the drawings for Embodiments 1 and 2 above are indicated by the same reference numerals, and description thereof is omitted.

FIG. 8 is a schematic plan view of a structure of the display device 1 in accordance with Embodiment 3.

Referring to FIG. 8, the display device 1 includes a frame area NDA and a display area DA. The display area DA of the display device 1 includes a plurality of pixels PIX, and each pixel PIX includes a red subpixel RSP (first subpixel), a green subpixel GSP (second subpixel), and a blue subpixel BSP (third subpixel). The present embodiment discusses, as an example, each pixel PIX including a red subpixel RSP, a green subpixel GSP, and a blue subpixel BSP, which is merely illustrative. Alternatively, for example, each pixel PIX may include a subpixel for another color in addition to the red subpixel RSP, the green subpixel GSP, and the blue subpixel BSP.

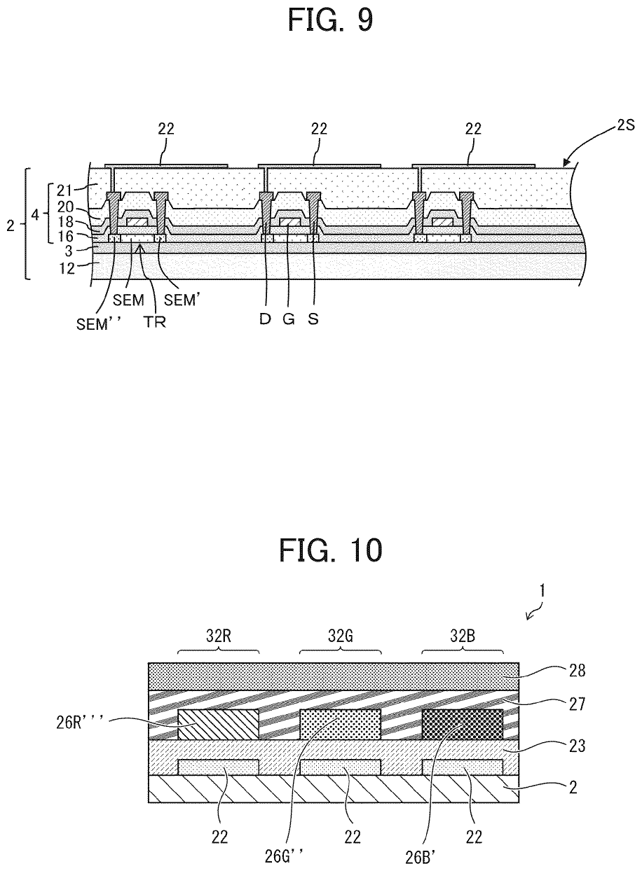

FIG. 9 is a schematic cross-sectional view of a structure of a substrate 2 including a transistor TR in the display device 1 in accordance with Embodiment 3.

Referring to FIG. 9, in the substrate 2 containing the transistor TR in the display device 1, there are provided a barrier layer 3 and a thin film transistor layer 4 containing the transistor TR, both of which are provided on a substrate 12 in this order when viewed from the substrate 12. Then, the first electrode 22 is provided on a surface 2S of the substrate 2 containing the transistor TR.

The substrate 12 may be, for example, either a resin substrate composed of a resin material such as a polyimide or a glass substrate. The present embodiment discusses an example in which the substrate 12 is a resin substrate composed of a resin material such as a polyimide so that the display device 1 can be a flexible display device, which is merely illustrative. When the display device 1 is a non-flexible display device, the substrate 12 may be a glass substrate.

The barrier layer 3 is a layer for preventing foreign objects such as water or oxygen from penetrating into the transistor TR and the light-emitting element of each color (detailed later) and can be, for example, a silicon oxide film, a silicon nitride film, a silicon oxynitride film, or a stack of any of these films. The films are formed by chemical vapor deposition (CVD).

The transistor TR portion of the thin film transistor layer 4 containing the transistor TR includes a semiconductor film SEM, doped semiconductor films SEM′ and SEM″, an inorganic insulating film 16, a gate electrode G, an inorganic insulating film 18, an inorganic insulating film 20, a source electrode S, a drain electrode D, and a planarization film 21. Meanwhile, the portion other than the transistor TR portion of the thin film transistor layer 4 containing the transistor TR includes the inorganic insulating film 16, the inorganic insulating film 18, the inorganic insulating film 20, and the planarization film 21.

The semiconductor films SEM, SEM′, and SEM″ may be made of, for example, a low-temperature polysilicon (LTPS) or an oxide semiconductor (e.g., an In—Ga—Zn—O-based semiconductor). The present embodiment discusses, as an example, the transistor TR having a top-gate structure, which is merely illustrative. Alternatively, the transistor TR may have a bottom-gate structure.

The gate electrode G, the source electrode S, and the drain electrode D may be, for example, a monolayer film of a metal containing at least one of aluminum, tungsten, molybdenum, tantalum, chromium, titanium, and copper or a stack of any of these films.

The inorganic insulating film 16, the inorganic insulating film 18, and the inorganic insulating film 20 may be, for example, a silicon oxide film, a silicon nitride film, a silicon oxynitride film, or a stack of any of these films. The films are formed by chemical vapor deposition (CVD).

The planarization film 21 may be made of, for example, an organic material, such as a polyimide or an acrylic, that can be provided by printing or coating technology.

Referring to FIG. 9, the thin film transistor layer 4 containing the transistor TR includes a control circuit containing the transistor TR for controlling each of a plurality of first electrodes 22.

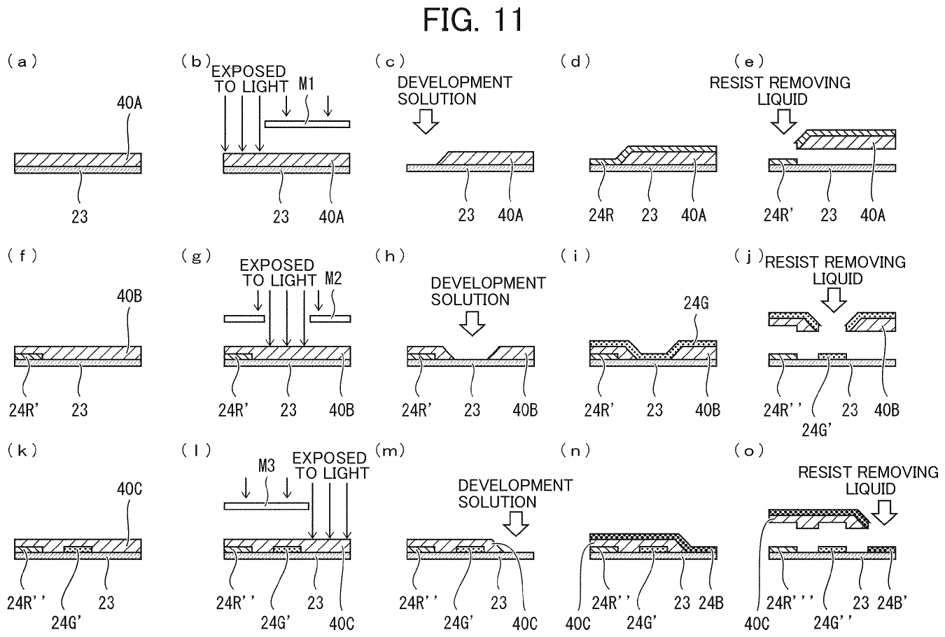

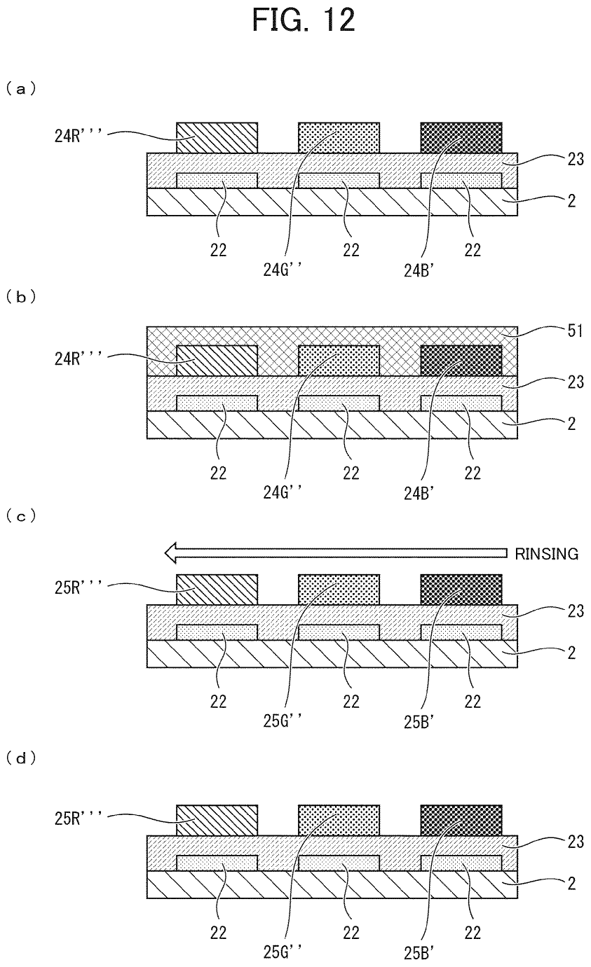

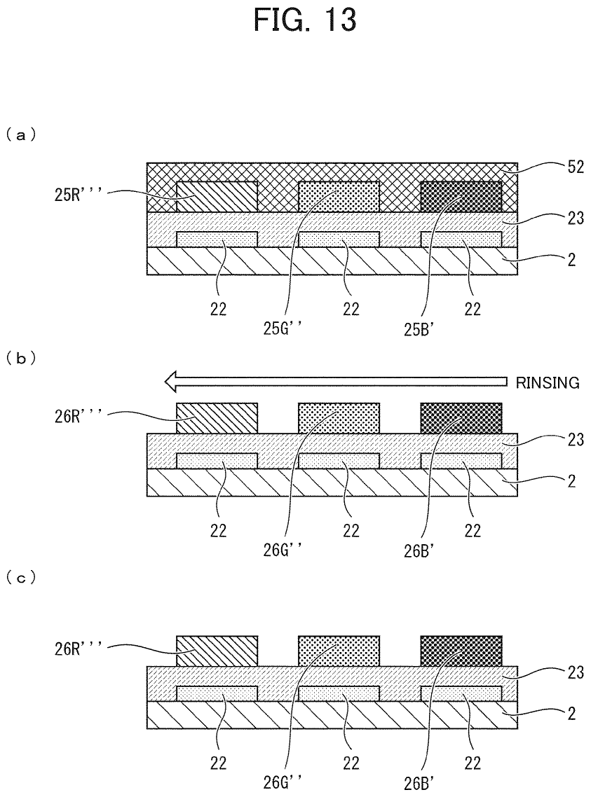

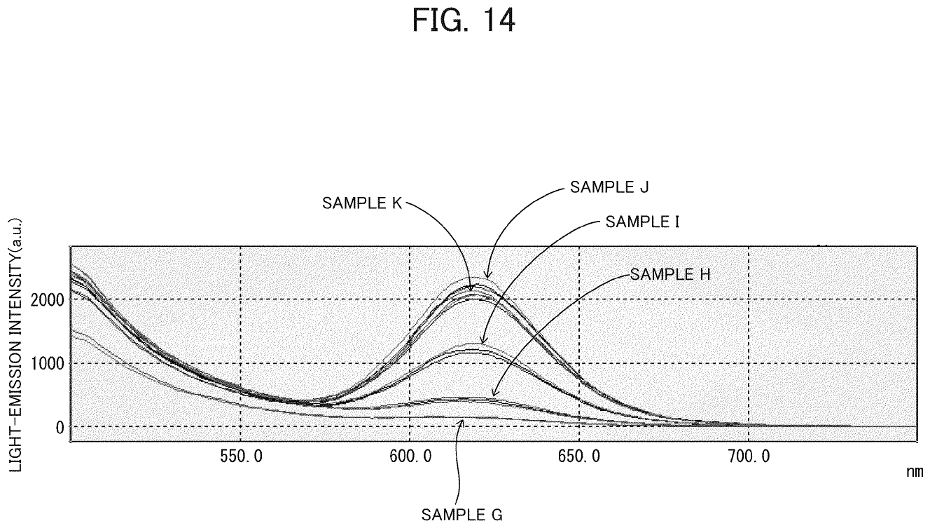

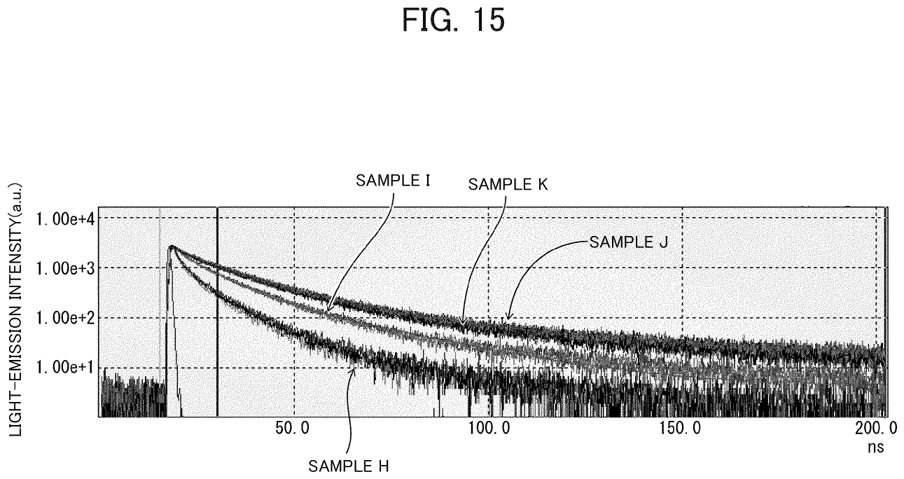

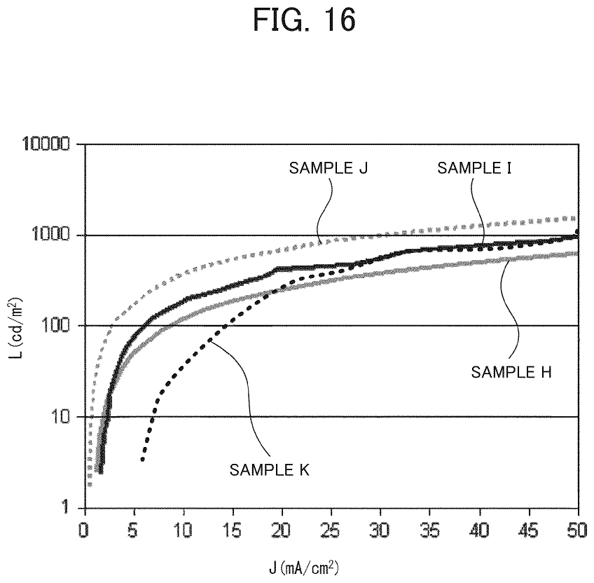

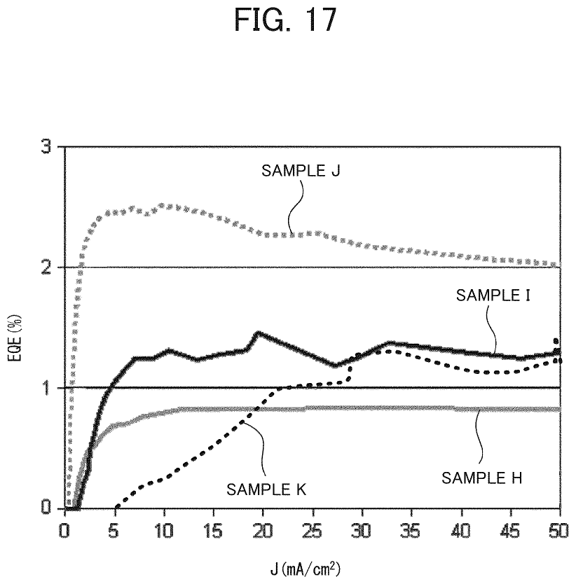

FIG. 10 is a schematic cross-sectional view of a structure of a red light-emitting element 32R, a green light-emitting element 32G, and a blue light-emitting element 32B in the display device 1 in accordance with Embodiment 3.

The red subpixel RSP shown in FIG. 8 includes the red light-emitting element 32R, the green subpixel GSP shown in FIG. 8 includes the green light-emitting element 32G, and the blue subpixel BSP shown in FIG. 8 includes the blue light-emitting element 32B.

The red light-emitting element 32R shown in FIG. 10 is a light-emitting element that has a forward-order stack structure including a stack of a first electrode 22, which is an anode, a hole transport layer 23, the red light-emitting layer 26R″′ containing quantum dots treated with a reducing agent and ligands and also patterned by lift-off, an electron transport layer 27, and a second electrode 28, which is a cathode, all of which are provided on the substrate 2 containing the transistor TR in this order when viewed from the substrate 2 containing the transistor TR. The green light-emitting element 32G shown in FIG. 10 is a light-emitting element that has a forward-order stack structure including a stack of the first electrode 22, which is an anode, the hole transport layer 23, the green light-emitting layer 26G″ containing quantum dots treated with a reducing agent and ligands and also patterned by lift-off, the electron transport layer 27, and the second electrode 28, which is a cathode, all of which are provided on the substrate 2 containing the transistor TR in this order when viewed from the substrate 2 containing the transistor TR. The blue light-emitting element 32B shown in FIG. 10 is a light-emitting element that has a forward-order stack structure including a stack of the first electrode 22, which is an anode, the hole transport layer 23, the blue light-emitting layer 26B′ containing quantum dots treated with a reducing agent and ligands and also patterned by lift-off, the electron transport layer 27, and the second electrode 28, which is a cathode, all of which are provided on the substrate 2 containing the transistor TR in this order when viewed from the substrate 2 containing the transistor TR.

Portions (a) of FIG. 11 to (o) of FIG. 11 are diagrams illustrating a lift-off patterning step for a red light-emitting layer, a green light-emitting layer, and a blue light-emitting layer respectively in the red light-emitting element 32R, the green light-emitting element 32G, and the blue light-emitting element 32B in the display device 1 in accordance with Embodiment 3.

The lift-off patterning step for a red light-emitting layer 24R″′, a green light-emitting layer 24G″, and a blue light-emitting layer 24B′ includes: a step of forming a resist layer 40A on the hole transport layer 23 shown in (a) of FIG. 11; a step of exposing the resist layer 40A to light via the mask M1 shown in (b) of FIG. 11; a step of developing using a development solution shown in (c) of FIG. 11 to form an opening through the resist layer 40A; a step of obtaining the red light-emitting layer 24R containing quantum dots by the application of a solution containing quantum dots and heat treatment shown in (d) of FIG. 11; and a step of obtaining the red light-emitting layer 24R′ patterned by removing the resist layer 40A using a resist removing liquid shown in (e) of FIG. 11. The lift-off patterning step for the red light-emitting layer 24R″′, the green light-emitting layer 24G″, and the blue light-emitting layer 24B′ further includes: a step of forming a resist layer 40B on the red light-emitting layer 24R′ and the hole transport layer 23 shown in (f) of FIG. 11; a step of exposing the resist layer 40B to light via a mask M2 shown in (g) of FIG. 11; a step of developing using a development solution shown in (h) of FIG. 11 to form an opening through the resist layer 40B; a step of obtaining the green light-emitting layer 24G containing quantum dots by the application of a solution containing quantum dots and heat treatment shown in (i) of FIG. 11; and a step of obtaining a green light-emitting layer 24G′ patterned by removing the resist layer 40B using a resist removing liquid shown in (j) of FIG. 11. The lift-off patterning step for the red light-emitting layer 24R″′, the green light-emitting layer 24G″, and the blue light-emitting layer 24B′ further includes: a step of forming a resist layer 40C on a red light-emitting layer 24R″, the green light-emitting layer 24G′, and the hole transport layer 23 shown in (k) of FIG. 11; a step of exposing the resist layer 40C to light via a mask M3 shown in (1) of FIG. 11; a step of developing using a development solution shown in (m) of FIG. 11 to form an opening through the resist layer 40C; a step of obtaining a blue light-emitting layer 24B containing quantum dots by the application of a solution containing quantum dots and heat treatment shown in (n) of FIG. 11; and a step of obtaining the blue light-emitting layer 24B′ patterned by removing the resist layer 40C using a resist removing liquid shown in (o) of FIG. 11. Note that the resist removing liquids shown in (e) of FIG. 11, (j) of FIG. 11, and (o) of FIG. 11 may be, for example, PGMEA, which is merely illustrative.

Note that if the step performed in an ambient environment and the step of obtaining the patterned light-emitting layer by removing the resist layer using the resist removing liquid are involved after the application step of applying the solution containing quantum dots shown in (d) of FIG. 11, but before the light-emitting layer processing step shown in (b) of FIG. 12, the quantum dots QD are adversely affected by, for example, the OH^{—} groups and the O₂^{—} groups on the surface of the quantum dots QD due to the adsorption of, for example, water and oxygen and further adversely affected during the removal of the resist layer using the resist removing liquid. These problems may be addressed by performing, in an inert gas atmosphere, for example, in a nitrogen atmosphere, the step performed in an ambient environment and the step of obtaining the patterned light-emitting layer by removing the resist layer using the resist removing liquid. To perform such steps in an inert gas atmosphere, however, large-sized and costly manufacturing equipment is required, which causes another problem of additional manufacturing cost.

In the present embodiment, the application step of applying a solution containing quantum dots shown in (d) of FIG. 11, the application step of applying a solution containing quantum dots shown in (i) of FIG. 11, and the application step of applying a solution containing quantum dots shown in (n) of FIG. 11, are performed in a nitrogen environment, and the other steps shown in FIG. 11 are all performed in an ambient environment. The present embodiment can therefore streamline manufacturing equipment and reduce manufacturing cost. Alternatively, the application step of applying a solution containing quantum dots shown in (d) of FIG. 11, the application step of applying a solution containing quantum dots shown in (i) of FIG. 11, and the application step of applying a solution containing quantum dots shown in (n) of FIG. 11 may be performed in an ambient environment. In such a case, the present embodiment can further streamline manufacturing equipment and reduce manufacturing cost.

The present embodiment has so far discussed an example in which: the red light-emitting layer, the green light-emitting layer, and the blue light-emitting layer are formed in this order; the quantum dots QD contained in the red light-emitting layer, which is formed before the others, have their properties most degraded; and the quantum dots QD contained in the green light-emitting layer, which is formed next, have their properties more degraded than do the quantum dots QD contained in the blue light-emitting layer, which is formed last, which is merely illustrative. Alternatively, the red light-emitting layer, the green light-emitting layer, and the blue light-emitting layer may be formed in any suitably determined order.

Portions (a) of FIG. 12, (b) of FIG. 12, (c) of FIG. 12, and (d) of FIG. 12 are diagrams illustrating a step of treating, with a reducing agent, the quantum dots QD contained in the red light-emitting layer 24R″′, the green light-emitting layer 24G″, and the blue light-emitting layer 24B′ patterned by lift-off shown in FIG. 11 that is a part of film formation steps of forming a light-emitting layer included in the step of manufacturing the display device 1 in accordance with Embodiment 3.

The red light-emitting layer 24R″′ containing the quantum dots QD shown in (a) of FIG. 12 is the red light-emitting layer 24R′″ patterned by lift-off shown in (o) of FIG. 11. A red light-emitting layer 24G″ containing the quantum dots QD shown in (a) of FIG. 12 is a red light-emitting layer 24G″ patterned by lift-off shown in (o) of FIG. 11. A red light-emitting layer 24B′ containing the quantum dots QD shown in (a) of FIG. 12 is a red light-emitting layer 24B′ patterned by lift-off shown in (o) of FIG. 11. The light-emitting layer processing step shown in (b) of FIG. 12 is the same step as the light-emitting layer processing step shown in (b) of FIG. 1, the rinsing step of rinsing off an excess of the reducing agent shown in (c) of FIG. 12 is the same step as the rinsing step of rinsing off an excess of the reducing agent shown in (c) of FIG. 1, and description thereof is therefore omitted. By performing the light-emitting layer processing step shown in (b) of FIG. 12 and the rinsing step of rinsing off an excess of the reducing agent shown in (c) of FIG. 12, a red light-emitting layer 25R″′ containing the quantum dots QD treated with a reducing agent, a green light-emitting layer 25G″ containing the quantum dots QD treated with a reducing agent, and a blue light-emitting layer 25B′ containing the quantum dots QD treated with a reducing agent can be obtained as shown in (d) of FIG. 12.

Portions (a) of FIG. 13, (b) of FIG. 13, and (c) of FIG. 13 are diagrams illustrating a step of further modifying, with ligands, the quantum dots QD contained in the red light-emitting layer 25R″′, the green light-emitting layer 25G″, and the blue light-emitting layer 25B′, that have been treated with a reducing agent, which is performed after the step shown in FIG. 12, that is another part of the film formation steps of forming a light-emitting layer included in the step of manufacturing the display device 1 in accordance with Embodiment 3.

As shown in (a) of FIG. 13, the quantum dots QD treated with a reducing agent and contained in the red light-emitting layer 25R″′, the green light-emitting layer 25G″, and the blue light-emitting layer 25B′ are further modified with ligands using a ligand solution 52. The ligand solution 52 contains ligands and a medium. Any type of ligands may be used so long as the ligands can be coordinated to the quantum dots QD. If the quantum dots QD are modified with ligands to improve the luminescence properties thereof as in the present embodiment, however, the ligands are preferably of such a type that the ligands, when coordinated to the quantum dots QD, do not impair the luminescence properties. Examples of the ligands that do not impair the luminescence properties include such types as oleic acid, dodecane thiol (DDT), TOP, and dodecyl amine. All these ligands are molecules that have a functional group that can be coordinated to the quantum dots QD and that include, for example, a carboxyl group, a thiol group, a phosphine group, or an amine group in the molecular backbone thereof.

The ligand solution 52 has a concentration of preferably from 0.01 mol/L to 2.0 mol/L, both inclusive, and more preferably from 0.1 mol/L to 1 mol/L, both inclusive, when it is taken into consideration that the lower the concentration, the less the effect expected due to a decrease in the frequency of the quantum dots QD coming into contact with the ligands and also that although the higher the concentration, the more the effect expected, it becomes difficult to remove excess ligands that can lead to poor flatness and smoothness of the surface because of the residue in the light-emitting layer. In the present embodiment, dodecane thiol (DDT) is used as the ligands, and PGMEA is used as the medium, to adjust the concentration of the ligand solution 52 to 0.3 mol/L (20 mg/mL). The medium is not limited in any particular manner so long as the medium can dissolve the ligands, but does not dissolve the light-emitting layer containing the quantum dots QD. When dodecane thiol (DDT) is used as the ligands, the medium is preferably, for example, ethanol, methanol, or PGMEA and more preferably PGMEA. This is because PGMEA exhibits a higher saturation solubility to various ligands, and hence offers higher freedom in solution concentration, than, for example, do ethanol and methanol.

The present embodiment discusses an example in which 60 seconds after the ligand solution 52 is dispensed dropwise onto the red light-emitting layer 25R′″, the green light-emitting layer 25G″, the blue light-emitting layer 25B′, and the hole transport layer 23, the spin coater is spun at 3,000 rpm for 60 seconds to treat the red light-emitting layer 25R′″, the green light-emitting layer 25G″, and the blue light-emitting layer 25B′ with the ligand solution 52 as shown in (a) of FIG. 13, which is merely illustrative. Alternatively, the red light-emitting layer 25R′″, the green light-emitting layer 25G″, and the blue light-emitting layer 25B′ may be treated with the ligand solution 52 by immersion, and the red light-emitting layer 25R′″, the green light-emitting layer 25G″, and the blue light-emitting layer 25B′ may be treated with the ligand solution 52 by dispersion. Even if the red light-emitting layer 25R′″, the green light-emitting layer 25G″, and the blue light-emitting layer 25B′ are treated with the ligand solution 52 by, for example, immersion or dispersion, excess ligands can be removed as in the rinsing step, shown in (b) of FIG. 13 (detailed later).

In the rinsing step shown in (b) of FIG. 13, excess ligands are preferably removed by rinsing using PGMEA in the same manner as the medium contained in the above-described ligand solution 52. Although, for example, ethanol or methanol may be used, PGMEA exhibits a higher saturation solubility, and hence offers a higher capability to dissolve excess ligands, than, for example, ethanol and methanol.

If the ligand solution 52 is dried, the rinsing step shown in (b) of FIG. 13 exhibits a lower dissolution rate of excess ligands into the rinsing medium and hence a lower efficiency in removing excess ligands, than treatment techniques under the same conditions. Therefore, it is preferable to perform the rinsing step immediately after the red light-emitting layer 25R″′, the green light-emitting layer 25G″, and the blue light-emitting layer 25B′ are treated with the ligand solution 52 before the ligand solution 52 is dried. In the present embodiment, as described above, the PGMEA is subjected to immersion by shaking for 30 seconds immediately after the red light-emitting layer 25R′″, the green light-emitting layer 25G″, and the blue light-emitting layer 25B′ are treated with the ligand solution 52 before the ligand solution 52 is dried. Note that although the longer the immersion time, the higher the removal ratio for excess ligands, since, for example, there could be adverse effects on components other than the red light-emitting layer 25R′″, the green light-emitting layer 25G″, and the blue light-emitting layer 25B′, and the ligands Lig could come off the surface of the quantum dots QD, the immersion time is preferably from 10 seconds to 180 seconds, both inclusive, and more preferably from 30 seconds to 90 seconds, both inclusive.

The rinsing step shown in (b) of FIG. 13 may be performed by a method other than the above-described immersion. For example, as described above, while the spin coater is spun after the ligand solution 52 is dispensed dropwise on the red light-emitting layer 25R′″, the green light-emitting layer 25G″, the blue light-emitting layer 25B′, and the hole transport layer 23, PGMEA may be dispensed dropwise more than once (e.g., 3 times) to perform centrifugal medium removal using a spin coater. As another alternative, after the step of treating the red light-emitting layer 25R′″, the green light-emitting layer 25G″, and the blue light-emitting layer 25B′ with the ligand solution 52, PGMEA may be dispensed dropwise more than once (e.g., 3 times) to perform centrifugal medium removal using a spin coater. As a further alternative, a medium removal step may be performed using a hotplate. In the centrifugal medium removal using a spin coater, the spin rate is not limited in any particular manner so long as the medium can be removed and is preferably from 1,000 rpm to 5,000 rpm, both inclusive, and more preferably from 2,000 rpm to 4,000 rpm, both inclusive. In addition, in the medium removal step using a hotplate, the heat-treatment temperature is not limited in any particular manner so long as the heat-treatment temperature does not adversely affect the substrate 42, the first electrode 22, the hole transport layer 23, the red light-emitting layer 26R″′ containing quantum dots treated with a reducing agent and ligands, the green light-emitting layer 26G″ containing quantum dots treated with a reducing agent and ligands, and the blue light-emitting layer 26B′ containing quantum dots treated with a reducing agent and ligands and is preferably from 40° C. to 200° C., both inclusive, and more preferably from 60° C. to 120° C., both inclusive.

As described in the foregoing, in the film formation step of forming a light-emitting layer that is included in the step of manufacturing the display device 1 in accordance with Embodiment 3, the rinsing step (first rinsing step) shown in (c) of FIG. 12 is performed between the light-emitting layer processing step shown in (b) of FIG. 12 and the ligand-modification step shown in (a) of FIG. 13, and the rinsing step (second rinsing step) shown in (b) of FIG. 13 is performed after the ligand-modification step shown in (a) of FIG. 13. This method of forming a light-emitting layer removes excess reducing agent and excess ligands by rinsing in the first rinsing step and the second rinsing step and can therefore restrain possible adverse effects of residual excess reducing agent and ligands on the light-emitting layer. Examples of the possible adverse effects of residual excess reducing agent and ligands on the light-emitting layer include poor flatness and smoothness of the light-emitting layer and non-uniform emission of light due to residual excess reducing agent and ligands. In addition, in each of the first rinsing step and the second rinsing step, the rinsing is preferably performed such that after the second rinsing step, an element contained in the reducing agent and also having a lower electronegativity than all the elements contained in the quantum dots QD remains on the surface of the quantum dots QD in a quantity of from 10 to 100, both inclusive, per quantum dot QD. This particular method of forming a light-emitting layer allows an element contained in the reducing agent and also having a lower electronegativity than all the elements contained in the quantum dots QD to remain on the surface of the quantum dots QD in a quantity of from 10 to 100, both inclusive, per quantum dot QD after the second rinsing step, and therefore can restrain possible adverse effects of the remaining element on the light-emitting layer in the post-process.

FIG. 14 is a diagram representing the light-emission intensity of a red light-emitting element (sample G), the light-emission intensity of a red light-emitting element (sample H), the light-emission intensity of a red light-emitting element (sample I), the light-emission intensity of a red light-emitting element (sample J), and the light-emission intensity of a red light-emitting element (sample K), when the red light-emitting elements are caused to fluoresce (photoluminescence or PL) under the same excitation light.

The light-emitting layer in red light-emitting element (sample G) is a red light-emitting layer formed by the lift-off patterning step shown in FIG. 11. Referring to FIG. 14, the light-emission intensity of the red light-emitting element (sample G) including the red light-emitting layer formed as described above decreases to such a level that the emitted light is unrecognizable.

The light-emitting layer in the red light-emitting element (sample H) is formed by treating, further with the above-described reducing agent, the quantum dots contained in the red light-emitting layer that has been subjected to the lift-off patterning step shown in FIG. 11. Referring to FIG. 14, the light-emission intensity of the red light-emitting element (sample H) including the light-emitting layer formed as described above improves to such a level that the emitted light is recognizable. That level is however still lower than the light-emission intensity of the red light-emitting element (sample I) including the red light-emitting layer formed by the application and removal of a medium in a nitrogen environment.

In contrast, the red light-emitting layer in the red light-emitting element (sample J) is formed by treating with the above-described reducing agent and thereafter further modifying, with ligands, the quantum dots contained in the red light-emitting layer that has been subjected to the lift-off patterning step shown in FIG. 11. Referring to FIG. 14, the light-emission intensity of the red light-emitting element (sample J) including the red light-emitting layer formed as described above is significantly higher than the light-emission intensity of the above-described red light-emitting element (sample H). This is presumably because although some of the ligands come off the quantum dots in the step using a resist removing liquid, ligands are coordinated once again to the quantum dots at the positions where ligands have come off in the ligand-modification treatment performed after the step using the resist removing liquid, thereby improving the capability of the quantum dots.

In addition, the red light-emitting layer in the red light-emitting element (sample K) is formed by after the above-described ligand-modification treatment, treating, further with the above-described reducing agent, the quantum dots contained in the red light-emitting layer that has been subjected to the lift-off patterning step shown in FIG. 11. Referring to FIG. 14, the light-emission intensity of the red light-emitting element (sample K) including the red light-emitting layer formed as described above is significantly higher than the light-emission intensity of the above-described red light-emitting element (sample H) and is at the substantially equivalent level to the light-emission intensity of the red light-emitting element (sample J). This is presumably because although some of the ligands come off the quantum dots in the step using a resist removing liquid, ligands are coordinated once again to the quantum dots at the positions where ligands have come off in the ligand-modification treatment performed after the step using the resist removing liquid, thereby improving the capability of the quantum dots.

FIG. 15 is a diagram representing results of measurement of the fluorescence lifetime (PL_{τ}) of the red light-emitting element (sample H), the red light-emitting element (sample I), the red light-emitting element (sample J), and the red light-emitting element (sample K) shown in FIG. 14.

Referring to FIG. 15, the red light-emitting element (sample H) (PL_{τ}=4.6 ns) has a shorter fluorescence lifetime than the red light-emitting element (sample I) (PL_{τ}=8.6 ns), whereas the red light-emitting element (sample J) (PL_{τ}=12.7 ns) and the red light-emitting element (sample K) (PL_{τ}=12.7 ns) have a longer fluorescence lifetime than the red light-emitting element (sample I) (PL_{τ}=8.6 ns).

FIG. 16 is a diagram representing a relationship between a current density and luminance for the red light-emitting element (sample H), the red light-emitting element (sample I), the red light-emitting element (sample J), and the red light-emitting element (sample K) shown in FIG. 14.

Referring to FIG. 16, the red light-emitting element (sample H) exhibits a lower luminance under the same current density than the red light-emitting element (sample I), whereas the red light-emitting element (sample J) exhibits a higher luminance under the same current density than the red light-emitting element (sample I). In addition, the red light-emitting element (sample K) exhibits a higher luminance under the same current density in a high current density region of at least 20 mA/cm² than the red light-emitting element (sample H) and exhibits an equivalent luminance under the same current density in a high current density region of at least 30 mA/cm² than the red light-emitting element (sample I).

FIG. 17 is a diagram representing a relationship between a current density and an external quantum efficiency (EQE) for the red light-emitting element (sample H), the red light-emitting element (sample I), the red light-emitting element (sample J), and the red light-emitting element (sample K) shown in FIG. 14.

Referring to FIG. 17, the red light-emitting element (sample H) exhibits a lower external quantum efficiency (EQE) under the same current density than the red light-emitting element (sample I), whereas the red light-emitting element (sample J) exhibits a higher external quantum efficiency (EQE) under the same current density than the red light-emitting element (sample I). In addition, the red light-emitting element (sample K) exhibits a higher luminance under the same current density in a high current density region of at least 20 mA/cm² than the red light-emitting element (sample H).

As described in the foregoing, it is understood that the quantum dots contained in the light-emitting layer obtained by the lift-off patterning step shown in FIG. 11 have the properties thereof improved even if treated only with a reducing agent, but further improved if treated both with a reducing agent and with ligands.

The display device 1 shown in FIG. 10 includes: the plurality of first electrodes 22, each of which is an anode; the red light-emitting layer 26R′″ provided on some of the plurality of first electrodes 22 in the red subpixel RSP (first subpixel) and also containing quantum dots; the green light-emitting layer 26G″ provided on some of the plurality of first electrodes 22 in the green subpixel GSP (second subpixel) and also containing quantum dots; the blue light-emitting layer 26B′ provided on some of the plurality of first electrodes 22 in the blue subpixel BSP (third subpixel) and also containing quantum dots; and the second electrode 28, which is a cathode. Then, the red light-emitting layer 26R′″ contains an element that has a lower electronegativity than all the elements contained in the quantum dots in the red light-emitting layer 26R′″, the green light-emitting layer 26G″ contains an element that has a lower electronegativity than all the elements contained in the quantum dots in the green light-emitting layer 26G″, and the blue light-emitting layer 26B′ contains an element that has a lower electronegativity than all the elements contained in the quantum dots in the blue light-emitting layer 26B′. The display device 1 enables improving, for example, fluorescence lifetime and luminous efficiency, streamlining manufacturing equipment, and reducing manufacturing cost, in the display device including a red light-emitting layer, a green light-emitting layer, and a blue light-emitting layer.

In the display device 1 shown in FIG. 10, the element, contained in the red light-emitting layer 26R′″, that has a lower electronegativity than all the elements contained in the quantum dots in the red light-emitting layer 26R″′, the element, contained in the green light-emitting layer 26G″ that has a lower electronegativity than all the elements contained in the quantum dots in the green light-emitting layer 26G″, and the element, contained in the blue light-emitting layer 26B′, that has a lower electronegativity than all the elements contained in the quantum dots in the blue light-emitting layer 26B′ preferably have an electronegativity less than or equal to the electronegativity of aluminum. Note that among the elements that have an electronegativity less than or equal to the electronegativity of aluminum, those that can be suitably used are, for example, Al, Li and Na.

In the display device 1 shown in FIG. 10 In addition, the element, contained in the red light-emitting layer 26R′″, that has a lower electronegativity than all the elements contained in the quantum dots in the red light-emitting layer 26R′″, the element, contained in the green light-emitting layer 26G″, that has a lower electronegativity than all the elements contained in the quantum dots in the green light-emitting layer 26G″, and the element, contained in the blue light-emitting layer 26B′, that has a lower electronegativity than all the elements contained in the quantum dots in the blue light-emitting layer 26B′ preferably have an electronegativity less than or equal to the electronegativity of lithium. Note that among the elements that have an electronegativity less than or equal to the electronegativity of lithium, those that can be suitably used are, for example, Li and Na.

Furthermore, in the display device 1 shown in FIG. 10, the element, contained in the red light-emitting layer 26R′″, that has a lower electronegativity than all the elements contained in the quantum dots in the red light-emitting layer 26R″′, the element, contained in the green light-emitting layer 26G″, that has a lower electronegativity than all the elements contained in the quantum dots in the green light-emitting layer 26G″, and the element, contained in the blue light-emitting layer 26B′, that has a lower electronegativity than all the elements contained in the quantum dots in the blue light-emitting layer 26B′ preferably have an electronegativity less than or equal to the electronegativity of sodium. Note that among the elements that have an electronegativity less than or equal to the electronegativity of sodium, those that can be suitably used are, for example, Na. In any of these configurations, the display device 1 enables further improving, for example, fluorescence lifetime and luminous efficiency.

In addition, in the display device 1 shown in FIG. 10, the element, contained in the red light-emitting layer 26R′″, that has a lower electronegativity than all the elements contained in the quantum dots in the red light-emitting layer 26R′″ preferably numbers from 10 to 100, both inclusive, per quantum dot contained in the red light-emitting layer 26R′″, the element, contained in the green light-emitting layer 26G″, that has a lower electronegativity than all the elements contained in the quantum dots in the green light-emitting layer 26G″ preferably numbers from 10 to 100, both inclusive, per quantum dot contained in the green light-emitting layer 26G″, and the element, contained in the blue light-emitting layer 26B′, that has a lower electronegativity than all the elements contained in the quantum dots in the blue light-emitting layer 26B′ preferably numbers from 10 to 100, both inclusive, per quantum dot contained in the blue light-emitting layer 26B'. In this configuration, the display device 1 enables further improving, for example, fluorescence lifetime and luminous efficiency.

The present embodiment has so far discussed, as an example, the display device 1 including the red light-emitting element 32R, the green light-emitting element 32G, and the blue light-emitting element 32B, all of which are light-emitting elements of an EL (electroluminescence) type that emit light by exciting quantum dots with electrical energy, which is merely illustrative. Alternatively, the present embodiment may be directed to a display device including light-emitting elements of a PL (photoluminescence) type that emit light by exciting quantum dots with light.

### Additional Remarks

The disclosure is not limited to the description of the embodiments above and may be altered within the scope of the claims. Embodiments based on a proper combination of technical means disclosed in different embodiments are encompassed in the technical scope of the disclosure. Furthermore, new technological features can be created by combining different technical means disclosed in the embodiments.

### INDUSTRIAL APPLICABILITY

The disclosure is applicable to methods of forming a light-emitting layer, methods of manufacturing a display device, and display devices.

1. A method of forming a light-emitting layer, the method comprising:
a light-emitting layer formation step of forming a light-emitting layer containing either quantum dots each including a core or quantum dots each including a core and a shell; and
a light-emitting layer processing step of treating the quantum dots in the light-emitting layer with a reducing agent after the light-emitting layer formation step.

2. The method according to claim 1, wherein
the reducing agent contains an element that has a lower electronegativity than all elements contained in the quantum dots, and
in the light-emitting layer processing step, the reducing agent is brought into contact with the quantum dots in the light-emitting layer.

3. The method according to claim 2, wherein the element, contained in the reducing agent, that has a lower electronegativity than all the elements contained in the quantum dots has an electronegativity less than or equal to an electronegativity of aluminum.

4. The method according to claim 2, wherein the element, contained in the reducing agent, that has a lower electronegativity than all the elements contained in the quantum dots has an electronegativity less than or equal to an electronegativity of lithium.

5. The method according to claim 2, wherein the element, contained in the reducing agent, that has a lower electronegativity than all the elements contained in the quantum dots has an electronegativity less than or equal to an electronegativity of sodium.

6. The method according to claim 3, wherein the element, contained in the reducing agent, that has a lower electronegativity than all the elements contained in the quantum dots is any of aluminum, lithium, and sodium.

7. The method according to claim 4, wherein the element, contained in the reducing agent, that has a lower electronegativity than all the elements contained in the quantum dots is either lithium or sodium.

8. The method according to claim 5, wherein the element, contained in the reducing agent, that has a lower electronegativity than all the elements contained in the quantum dots is sodium.

9. The method according to claim 1, wherein
the reducing agent contains at least one of sodium borohydride, lithium borohydride, and lithium aluminum hydride, and
in the light-emitting layer processing step, the reducing agent is brought into contact with the quantum dots contained in the light-emitting layer.

10. The method according to claim 1, wherein in the light-emitting layer processing step, the reducing agent and ligands are brought into contact with the quantum dots contained in the light-emitting layer.

11. The method according to claim 1, further comprising a ligand-modification step of bringing ligands and the quantum dots contained in the light-emitting layer into contact with each other between the light-emitting layer formation step and the light-emitting layer processing step.

12. The method according to claim 1, further comprising a ligand-modification step of bringing ligands and the quantum dots contained in the light-emitting layer into contact with each other after the light-emitting layer processing step.

13. The method according to claim 1, further comprising a rinsing step after the light-emitting layer processing step.

14. The method according to claim 12, further comprising
a first rinsing step between the light-emitting layer processing step and the ligand-modification step, and
a second rinsing step after the ligand-modification step.

15. The method according to claim 13, wherein in the rinsing step, rinsing is performed so that an element, contained in the reducing agent, that has a lower electronegativity than all elements contained in the quantum dots remains on a surface of the quantum dots in a quantity of 10 to 100, both inclusive, per quantum dot after the rinsing step.

16. The method according to claim 14, wherein in each of the first rinsing step and the second rinsing step, rinsing is performed so that an element, contained in the reducing agent, that has a lower electronegativity than all elements contained in the quantum dots remains on a surface of the quantum dots in a quantity of 10 to 100, both inclusive, per quantum dot after the second rinsing step.

17. The method according to claim 1, wherein
the light-emitting layer formation step is a step of forming a plurality of different light-emitting layers, and
the light-emitting layer formation step comprises:
a first resist film formation step of forming a first resist film having a first opening;
a step of forming a first light-emitting layer containing first quantum dots on the first resist film and in the first opening as one of the plurality of different light-emitting layers;
a step of detaching the first resist film;
a second resist film formation step of forming a second resist film covering the first light-emitting layer in the first opening and having a second opening in a different location than the first opening;
a step of forming a second light-emitting layer containing second quantum dots on the second resist film and in the second opening as another one of the plurality of different light-emitting layers;
a step of detaching the second resist film;
a third resist film formation step of forming a third resist film covering the first light-emitting layer in the first opening and the second light-emitting layer in the second opening and having a third opening in a different location than the first opening and the second opening;
a step of forming a third light-emitting layer containing third quantum dots on the third resist film and in the third opening as a further one of the plurality of different light-emitting layers; and
a step of detaching the third resist film.

18. The method according to claim 1, wherein the light-emitting layer formation step is performed in atmosphere.

19. A method of manufacturing a display device, the method comprising a step of forming a light-emitting layer on a substrate by the method according to claim 1.

20. A display device comprising:
a first subpixel, a second subpixel, and a third subpixel;
a first light-emitting layer provided in the first subpixel and containing either first quantum dots each including a core or first quantum dots each including a core and a shell;
a second light-emitting layer provided in the second subpixel and containing either second quantum dots each including a core or second quantum dots each including a core and a shell; and
a third light-emitting layer provided in the third subpixel and containing either third quantum dots each including a core or third quantum dots each including a core and a shell, wherein
the first light-emitting layer contains an element that has a lower electronegativity than all elements contained in the first quantum dots,
the second light-emitting layer contains an element that has a lower electronegativity than all elements contained in the second quantum dots, and
the third light-emitting layer contains an element that has a lower electronegativity than all elements contained in the third quantum dots.

21-27. (canceled)
